(19) United States
(12) Patent Application Publication
(10) Pub. No.: US 2026/0068746 A1
(43) Pub. Date: Mar. 5, 2026

(54) SEMICONDUCTOR PACKAGE MOLD COMPOUND DAMS

(71) Applicant: TEXAS INSTRUMENTS INCORPORATED, Dallas, TX (US)

(72) Inventors: Masamitsu MATSUURA, Beppu-Shi Oita-Prefecture (JP); Tatsuhiro SHIMIZU, Hayami-Gun Oita-Prefecture (JP); Daiki KOMATSU, Beppu-Shi Oita-Prefecture (JP); Kengo AOYA, Beppu-Shi Oita-Prefecture (JP); Anindya PODDAR, Sunnyvale, CA (US)

(21) Appl. No.: 18/822,180

(22) Filed: Aug. 31, 2024

(51) Int. Cl. H01L 23/24; B81B 7/00; B81C 1/00; H01L 21/56; H01L 23/29; H01L 23/31

(52) U.S. Cl. CPC H01L 23/24; B81B 7/0061; B81C 1/00309

(57) ABSTRACT

In examples, a semiconductor package includes a semiconductor die including a device side having circuitry formed therein and a non-device side opposite the device side. The semiconductor package includes a mold compound dam on the device side, the mold compound dam comprising a non-metallic material. The semiconductor package includes a mold compound on the device side of the semiconductor die and contacting an outer wall of the mold compound dam, the mold compound absent from a cavity defined by the mold compound dam.

### BACKGROUND

Semiconductor wafers are circular pieces of semiconductor material, such as silicon, that are used to manufacture semiconductor chips. Generally, complex manufacturing processes are used to form numerous integrated circuits on a single wafer. The formation of such circuits on a wafer is called fabrication. After wafer fabrication, the wafer is cut into multiple pieces, called semiconductor dies, with each die containing one of the circuits. The cutting, or sawing, of the wafer into individual dies is called singulation. An individual die is then coupled to a die pad and to conductive terminals, sometimes called “leads.” The resulting structure is subsequently covered with a mold compound to produce a package.

### SUMMARY

In examples, a semiconductor package includes a semiconductor die including a device side having circuitry formed therein and a non-device side opposite the device side. The semiconductor package includes a mold compound dam on the device side, the mold compound dam comprising a non-metallic material. The semiconductor package includes a mold compound on the device side of the semiconductor die and contacting an outer wall of the mold compound dam, the mold compound absent from a cavity defined by the mold compound dam.

In examples, a method for manufacturing a semiconductor package includes forming a mold compound dam circumscribing a sensor on a semiconductor wafer, the mold compound dam comprising a non-metallic material and comprising a cantilevered portion distal to the sensor relative to the semiconductor wafer, the cantilevered portion suspended over the sensor and defining an orifice axially aligned with the sensor, the orifice having a diameter between 30 microns and 1000 microns, the cantilevered portion having a decreasing thickness measured from a top surface of the cantilevered portion to a bottom surface of the cantilevered portion. The method includes back grinding and singulating the semiconductor wafer to produce a semiconductor die, coupling the semiconductor die to a die pad, wire bonding the semiconductor die to a conductive terminal, and covering the semiconductor die, the die pad, and the conductive terminal with a mold compound. The mold compound dam precludes the mold compound from flowing into a cavity defined by the mold compound dam and precluding the mold compound from contacting the sensor.

### BRIEF DESCRIPTION OF THE DRAWINGS

FIG. 1 is a flow diagram of a method for manufacturing a semiconductor package using a mold compound dam, in accordance with various examples.

FIGS. 2A-9 are a process flow depicting the manufacture of a semiconductor package using a mold compound dam, in accordance with various examples.

FIGS. 10A-18 are a process flow depicting the manufacture of a semiconductor package using a mold compound dam, in accordance with various examples.

FIG. 19 is a flow diagram of a method for manufacturing a semiconductor package using a mold compound dam, in accordance with various examples.

FIGS. 20A-28 are a process flow depicting the manufacture of a semiconductor package using a mold compound dam, in accordance with various examples.

FIG. 29 is a flow diagram of a method for manufacturing a semiconductor package using a mold compound dam, in accordance with various examples.

FIGS. 30A-37C are a process flow depicting the manufacture of a semiconductor package using a mold compound dam, in accordance with various examples.

FIG. 38 is a flow diagram of a method for manufacturing a semiconductor package using a mold compound dam, in accordance with various examples.

FIGS. 39A-48C are a process flow depicting the manufacture of a semiconductor package using a mold compound dam, in accordance with various examples

FIG. 49 is a cross-sectional view of a semiconductor package manufactured according to the techniques described herein, in accordance with various examples.

FIGS. 50A-52 depict semiconductor packages manufactured according to the techniques described herein, in accordance with various examples.

FIGS. 53A-C depict a semiconductor package manufactured according to the techniques described herein, in accordance with various examples.

FIGS. 54A-C depict a semiconductor package manufactured according to the techniques described herein, in accordance with various examples.

FIGS. 55A-C depict a semiconductor package manufactured according to the techniques described herein, in accordance with various examples.

FIGS. 56A-C depict a semiconductor package manufactured according to the techniques described herein, in accordance with various examples.

FIG. 57 is a block diagram of an electronic device including a semiconductor package manufactured according to the techniques described herein, in accordance with various examples.

### DETAILED DESCRIPTION

Sensor packages (e.g., humidity sensors, pressure sensors, gas sensors, chemical sensors, light sensors) require an opening on the semiconductor die surface to expose the sensing element to the ambient environment. Forming this opening while maintaining package integrity and performance introduces multiple technical challenges. One technical challenge associated with forming such openings is package size limitation. The open cavity package commonly used in the market is produced through a specialized molding technology, which dictates the design rules for the opening area. This means that the size and pitch of the opening are constrained by the capabilities of the molding tool. Additionally, the accuracy of die attachment plays a significant role in determining the final design, as any misalignment can lead to functional and structural problems.

Another technical challenge is the risk of semiconductor die cracking. The process of creating an opening on the die surface often involves the physical contact of the molding tool tip with the die. This contact, combined with inherent variations in the thickness of the die and the die attach material, can lead to interlayer dielectric (ILD) cracks. Any compromises in the structural integrity of the die can result in device failure. Ensuring consistent thickness and high precision during the attachment process can mitigate this risk. Manufacturers must employ stringent quality control measures and advanced materials to maintain uniformity and prevent cracks, which adds complexity and cost to the manufacturing process.

Contamination and damage to the die surface represent another technical challenge to the manufacture of sensor packages. During the assembly and packaging process, the exposed die surface is vulnerable to contamination from the harsh manufacturing environment, such as during reflow processes. Contaminants can degrade the performance of the sensing element, leading to inaccurate readings and reduced sensor lifespan.

This disclosure describes various examples of semiconductor package mold compound dams that mitigate the technical challenges described above. The mold compound dams are useful to form mold compound cavities through which package sensors are exposed to the ambient environment. The mold compound dams are usable in lieu of the specialized mold chase tools that result in undesirably large semiconductor packages and physical damage to dies and sensors, as described above. Example semiconductor packages include a semiconductor die including a device side having circuitry formed therein and a non-device side opposite the device side. The packages include a sensor on the device side of the semiconductor die and a cylindrical mold compound dam on the device side and encircling the sensor. The mold compound dam is composed of a non-metallic material. The packages also include a mold compound on the device side of the semiconductor die and contacting an outer wall of the mold compound dam facing away from the sensor. The mold compound is absent from a cavity defined by the mold compound dam, because during the mold application process (e.g., mold injection in a mold chase), the mold compound dam prevents the mold compound from flowing into the cavity, where the sensor is located. Because the mold compound dam is used instead of a specialized mold chase to create the sensor cavity, the technical challenges described above-such as the enlarged package size and physical damage to the semiconductor die and sensors-are resolved.

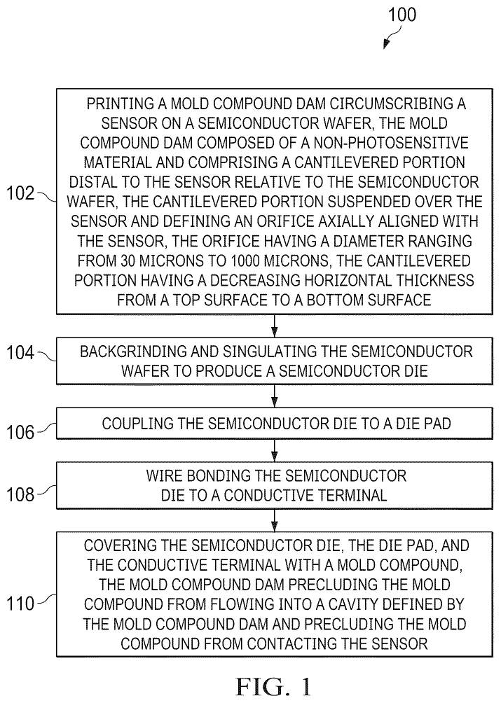

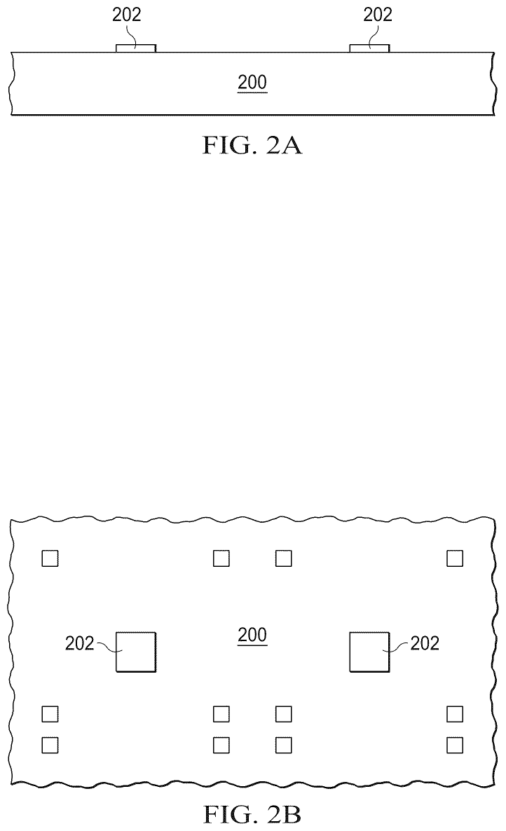

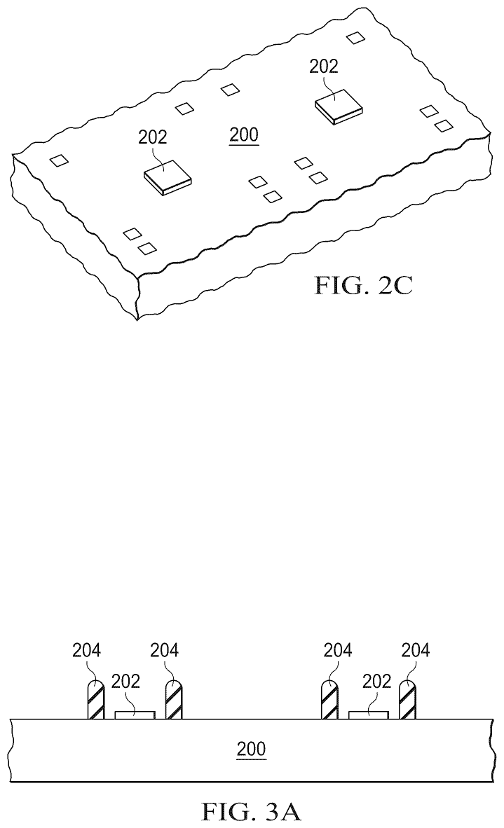

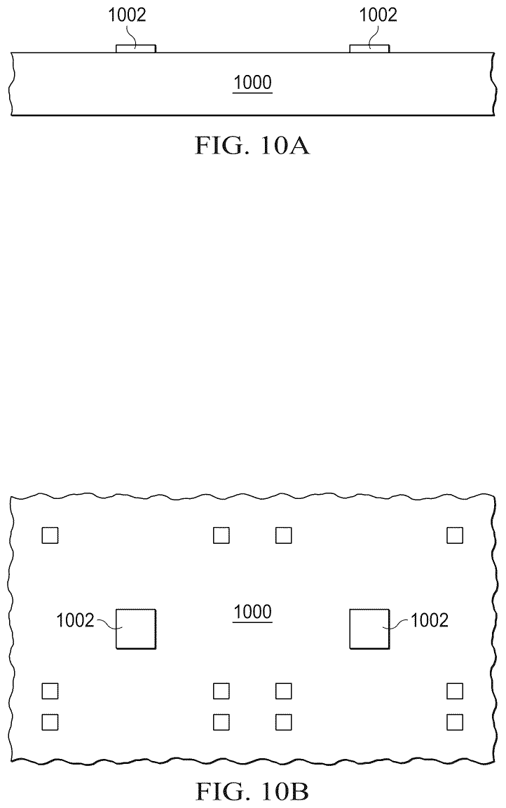

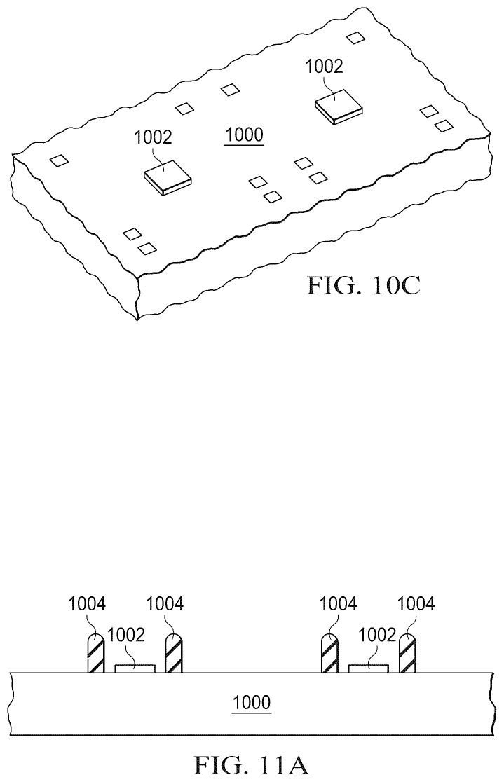

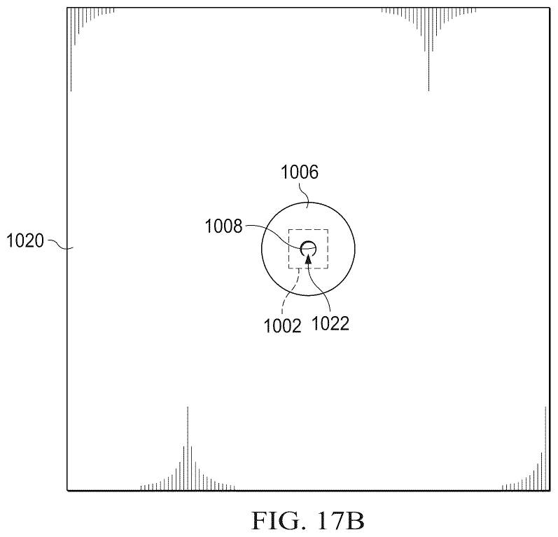

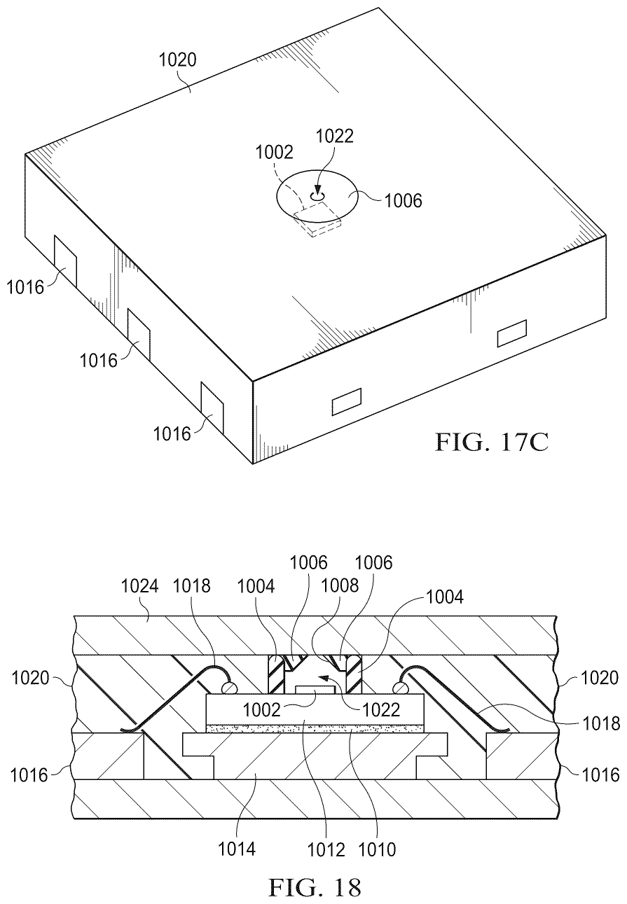

FIG. 1 is a flow diagram of a method 100 for manufacturing a semiconductor package using a mold compound dam, in accordance with various examples. FIGS. 2A-9 are a process flow depicting the manufacture of a semiconductor package using a mold compound dam, in accordance with various examples. FIGS. 10A-18 are a process flow depicting the manufacture of a semiconductor package using a mold compound dam, in accordance with various examples. Accordingly, the method 100 is now described in parallel with the process flow of FIGS. 2A-9 and the process flow of FIGS. 10A-18.

The method 100 may include printing a mold compound dam circumscribing a sensor on a semiconductor wafer (102). The mold compound dam is composed of a non-metallic material (which may be photosensitive or non-photosensitive in various examples) and may comprise a cantilevered portion distal to the sensor relative to the semiconductor wafer (102). The cantilevered portion may be suspended over the sensor and may define an orifice axially aligned with the sensor (102). The orifice may have a diameter ranging from 30 microns to 1000 microns, with the cantilevered portion having a decreasing horizontal thickness (as measured from an outer surface of the cantilevered portion to an inner surface of the cantilevered portion) from a top surface of the cantilevered portion to a bottom surface of the cantilevered portion and/or a decreasing vertical thickness (as measured from a top surface of the cantilevered portion to a bottom surface of the cantilevered portion) from the perimeter of the cantilevered portion to a centermost portion of the cantilevered portion (102).

FIG. 2A is a cross-sectional view of a semiconductor wafer 200 (e.g., a silicon, silicon carbide, gallium arsenide, or gallium nitride wafer) having multiple sensors 202 formed on a device side of the semiconductor wafer 200. The semiconductor wafer 200 may have any suitable number of sensors 202 formed thereon. FIGS. 2B and 2C are top-down and perspective views of the structure of FIG. 2A, in accordance with various examples.

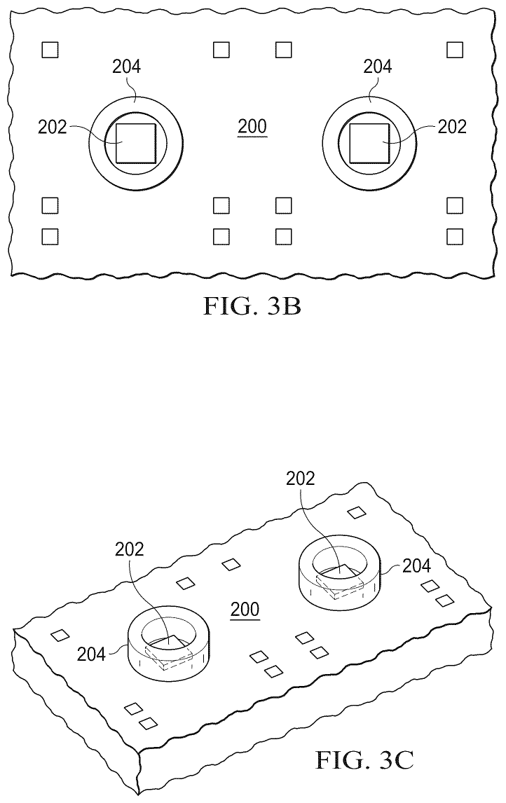

FIG. 3A is a cross-sectional view of the structure of FIG. 2A, except that mold compound dams 204 are formed on the semiconductor wafer 200, each mold compound dam 204 circumscribing a different sensor 202. In examples, each mold compound dam 204 has a flat bottom surface that couples to the semiconductor wafer 200 and has a rounded, donut-shaped top surface opposite the bottom surface of that mold compound dam 204. In other examples, each mold compound dam 204 has a flat bottom surface and a flat, non-rounded top surface. Other shapes are contemplated and included in the scope of this disclosure. The height of each mold compound dam 204 on the semiconductor wafer 200 is roughly equivalent, and is at least the same height as that of bond wires that are to be subsequently coupled to the semiconductor wafer 200, such that when a mold chase lid is lowered to contact the top surface of the mold compound dam 204 and mold compound is applied, the thickness of the mold compound will be adequate to fully cover all bond wires. The mold compound dams 204 have horizontal thicknesses that are between 10 microns and 750 microns, with a thickness below this range being disadvantageous because the mold compound dams 204 are unable to provide adequate mechanical support to the mold compound contacting the mold compound dams 204, and with a thickness above this range being disadvantageous because the mold compound dams 204 occupy an unacceptable amount of volume within the semiconductor packages. The mold compound dams 204 may be formed of any suitable non-photosensitive or photosensitive material that is non-metallic, such as polyimide, polybenzoxazole (PBO), any suitable polymer, ink, epoxy (e.g., SU-8), etc. The mold compound dams 204 may be formed using any suitable technique, such as inkjet printing, nano imprinting, stencil printing, etc. Non-metallic mold compound dams are superior to metallic mold compound dams because metallic mold compound dams entail tedious and expensive manufacturing techniques, such as photolithography-based plating techniques. Further, metallic mold compound dams present a relatively greater risk of damage caused by thermal mismatch and mechanical stress due to widely differing coefficients of thermal expansion, the risk of corrosion and oxidation, particularly when metallic mold compound dams will be exposed to the ambient environment to facilitate sensing, the risk of increased weight, the risk of unintended electrical conductivity and short circuits, and the risk of electromagnetic interference in certain applications. These risks are mitigated by non-metallic mold compound dams, including photosensitive and non-photosensitive mold compound dams, because non-metallic mold compound dams either lack metal entirely, or lack metal that would be sufficient to meaningfully increase the aforementioned risks. FIG. 3B is a top-down view of the structure of FIG. 3A, in accordance with various examples, and FIG. 3C is a perspective view of the structure of FIG. 3A, in accordance with various examples.

Similar to the process flow of FIGS. 2A-9, the process flow of FIGS. 10A-18 begins with the formation of sensors 1002 on a device side of a semiconductor wafer 1000 (FIG. 10A). The various properties of the sensors 1002 and the semiconductor wafer 1000 are similar or identical to those described above for the sensors 202, respectively. FIG. 10B is a top-down view of the structure of FIG. 10A, in accordance with various examples. FIG. 10C is a perspective view of the structure of FIG. 10A, in accordance with various examples.

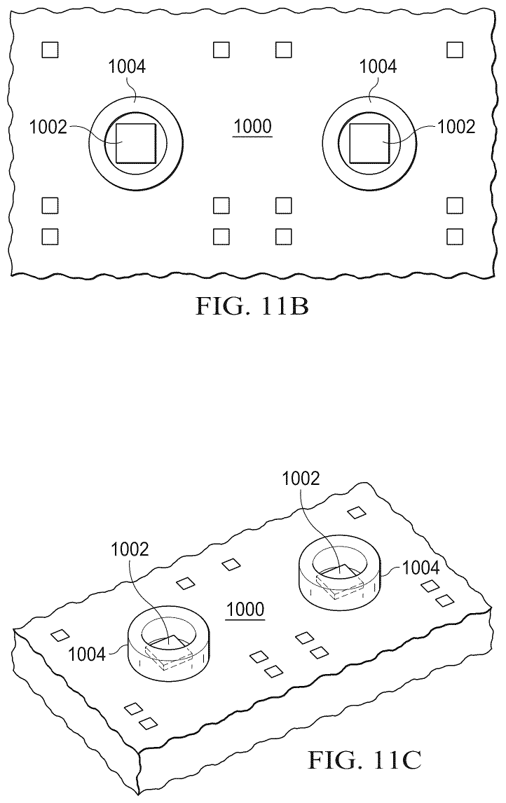

FIG. 11A is a cross-sectional view of the structure of FIG. 10A, except with the addition of mold compound dams 1004, in accordance with various examples. The description provided herein for the mold compound dams 204 also may apply, in whole or in part, to the mold compound dams 1004. FIG. 11B is a top-down view of the structure of FIG. 11A, in accordance with various examples. FIG. 11C is a perspective view of the structure of FIG. 11A, in accordance with various examples.

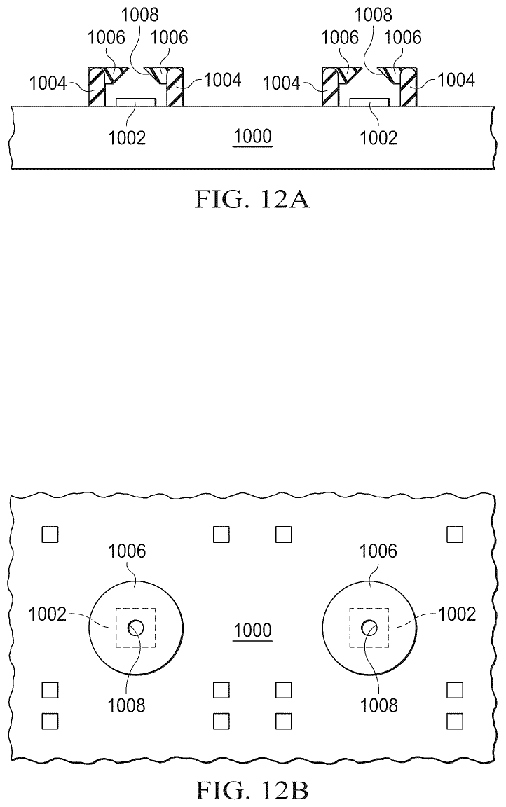

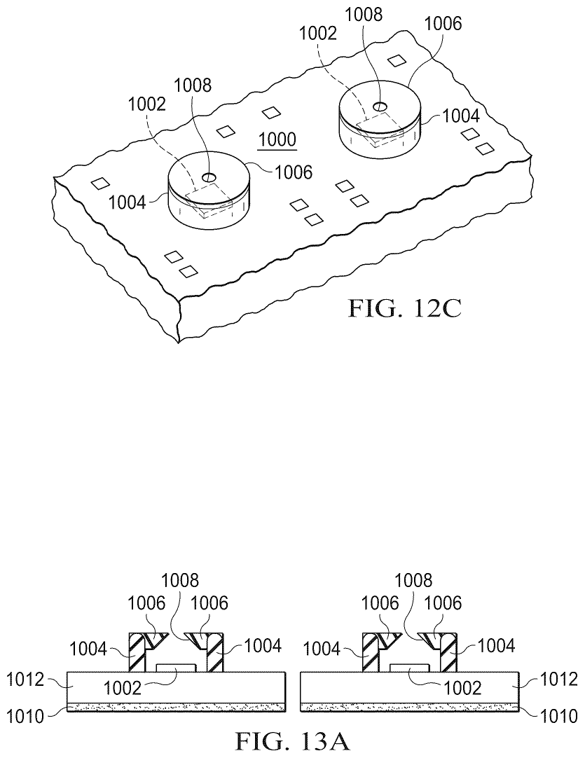

FIG. 12A is a cross-sectional view of the structure of FIG. 11A, except that the mold compound dams 1004 have been modified to include a cantilevered portion 1006. The cantilevered portion 1006 may be circular in shape when viewed from a top view, and may be coupled to the remainder of the mold compound dam 1004 along a perimeter of the cantilevered portion 1006. The remainder of the cantilevered portion 1006 may be suspended over the sensor 1002, in a cantilevered manner. The center of the cantilevered portion 1006 includes an orifice 1008. The orifice 1008 may be in vertical alignment with the sensor 1002, such that a line extending orthogonally through the sensor 1002 also extends through the orifice 1008. In examples, the cantilevered portion 1006 is thickest (in the vertical direction) closest to an outer perimeter of the cantilevered portion 1006, and gradually thins approaching the orifice 1008, as shown. The diameter of the orifice 1008 ranges from 30 microns to 1000 microns, with a diameter below this range being disadvantageous because of decreased sensing accuracy, and with a diameter above this range being disadvantageous because of the risk of sensor contamination.

The cantilevered portion 1006 may be formed using any suitable technique. For example, an inkjet printing or additive manufacturing technique may be useful to form the cantilevered portion 1006. Example manufacturing techniques useful to form the cantilevered portion 1006 also may be found in Stephanie Walker et al., Zero Support 3D Printing of Thermoset Silicone Via Simultaneous Control of Both Reaction Kinetics and Transient Rheology, 3D Printing and Additive Manufacturing (Vol. 6, No. 3) (2019), which is incorporated herein by reference in its entirety. Other manufacturing techniques are contemplated and included in the scope of this disclosure. FIG. 12B is a top-down view of the structure of FIG. 12A, in accordance with various examples.

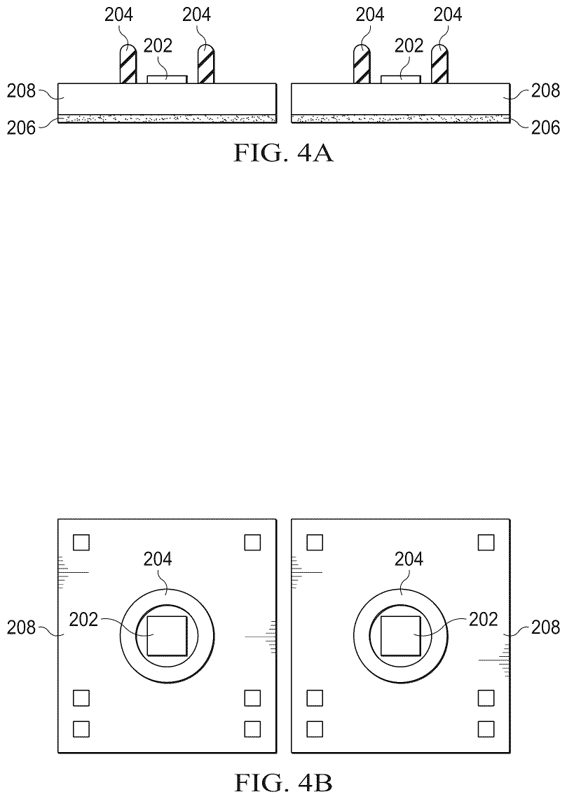

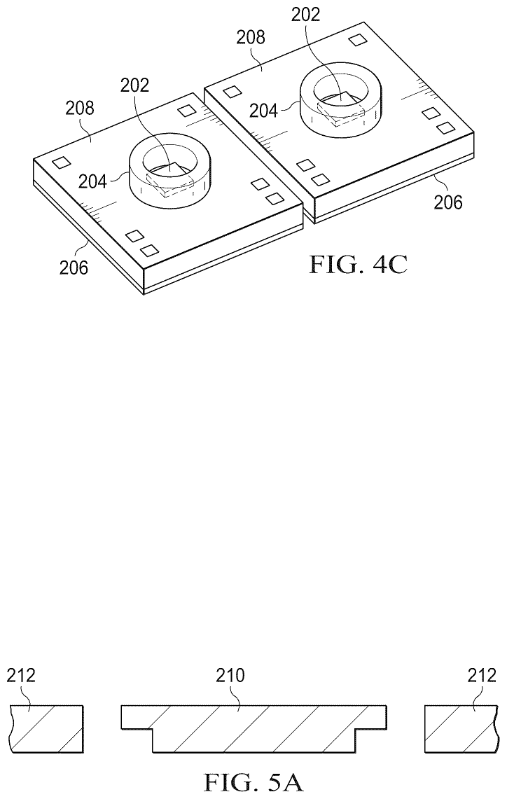

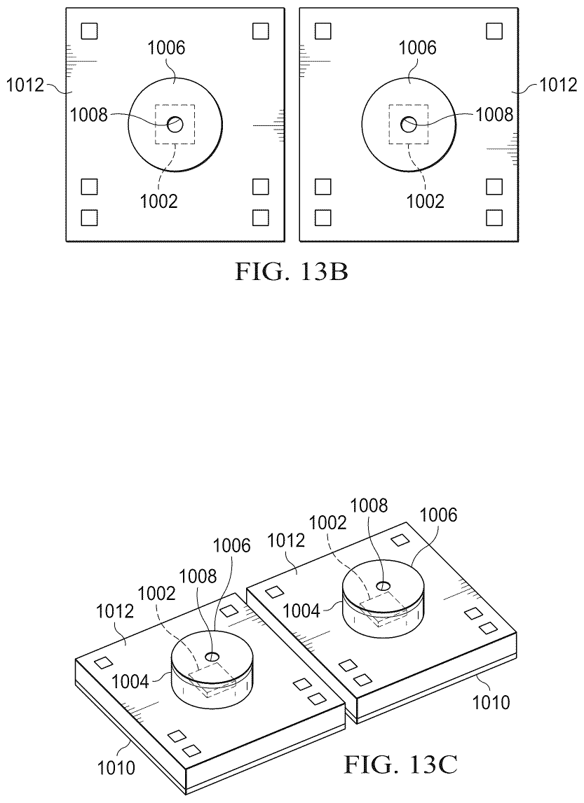

The method 100 may comprise backgrinding and singulating the semiconductor wafer to produce individual semiconductor dies (104). In the process flow of FIGS. 2A-9, FIG. 4A depicts a cross-sectional view of the structure of FIG. 3A, except that the semiconductor wafer 200 has been backgrinded, a die attach film 206 has been applied to a backside of the thinned semiconductor wafer 200, and the semiconductor wafer 200 has been singulated (e.g., by mechanical or laser saw) to produce individual semiconductor dies 208. FIG. 4B is a top-down view of the structures of FIG. 4A, in accordance with various examples. FIG. 4C is a perspective view of the structures of FIG. 4A, in accordance with various examples. Similarly, in the process flow of FIGS. 10A-18, FIG. 13A depicts a cross-sectional view of the structure of FIG. 12A, except that the semiconductor wafer 1000 has been backgrinded, a die attach film 1010 has been applied to a backside of the thinned semiconductor wafer 1000, and the semiconductor wafer 1000 has been singulated (e.g., by mechanical or laser saw) to produce individual semiconductor dies 1012. FIG. 13B is a top-down view of the structures of FIG. 13A, in accordance with various examples. FIG. 13C is a perspective view of the structures of FIG. 13A, in accordance with various examples.

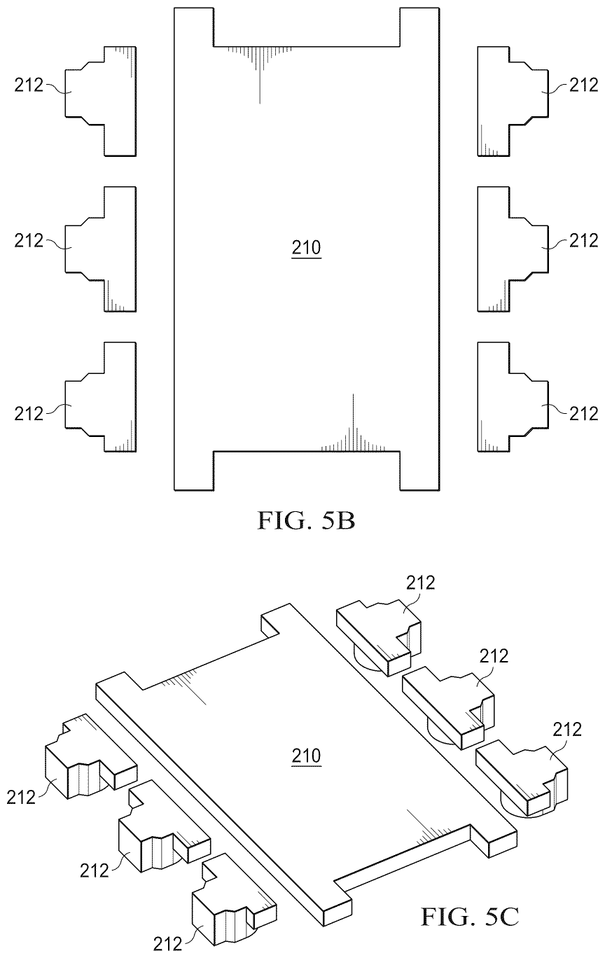

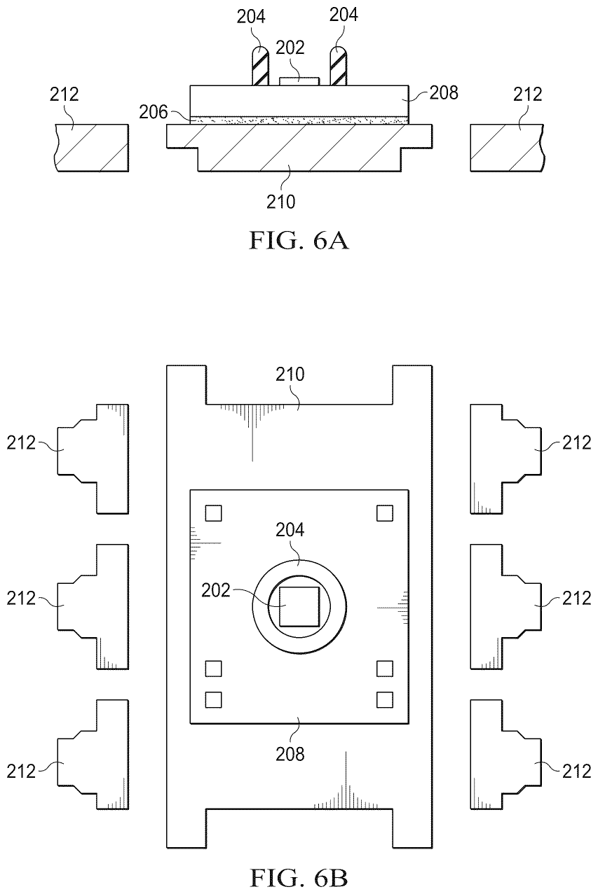

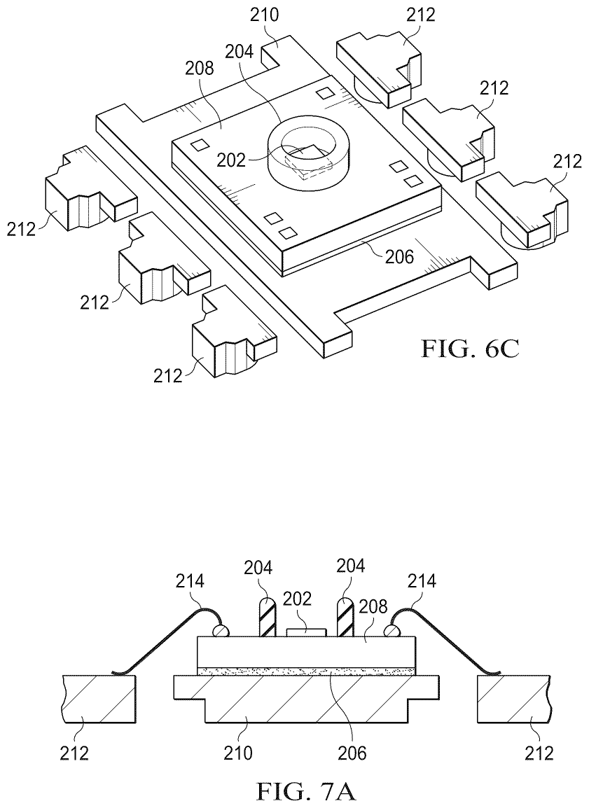

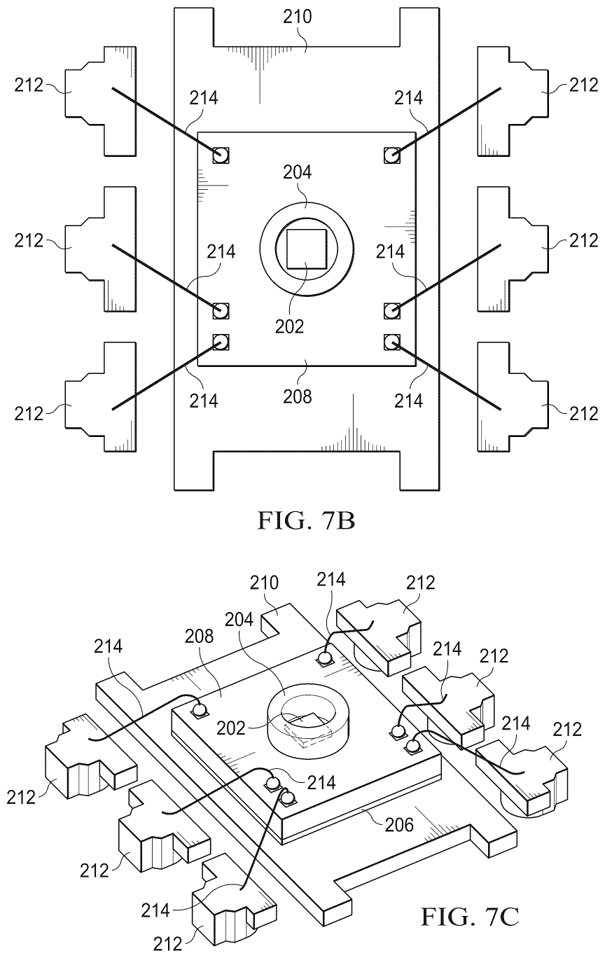

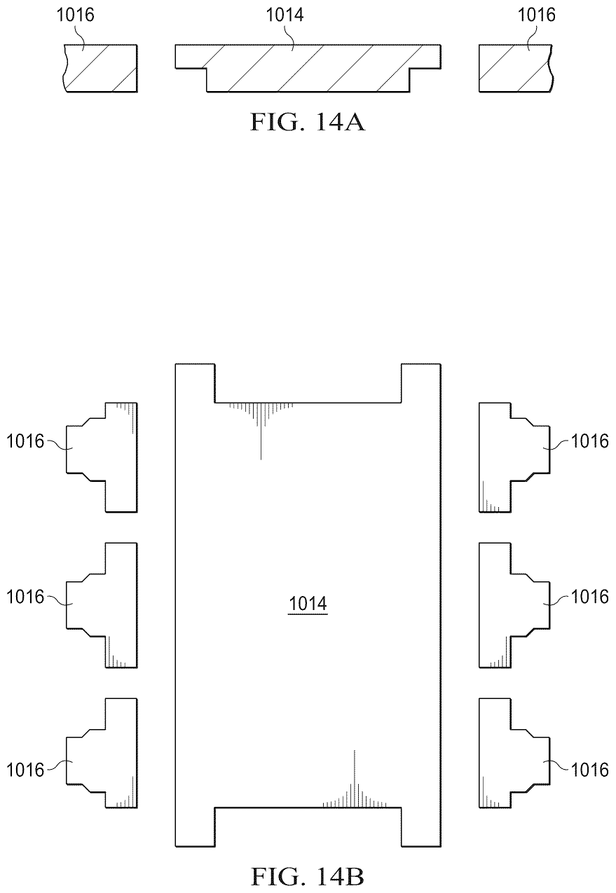

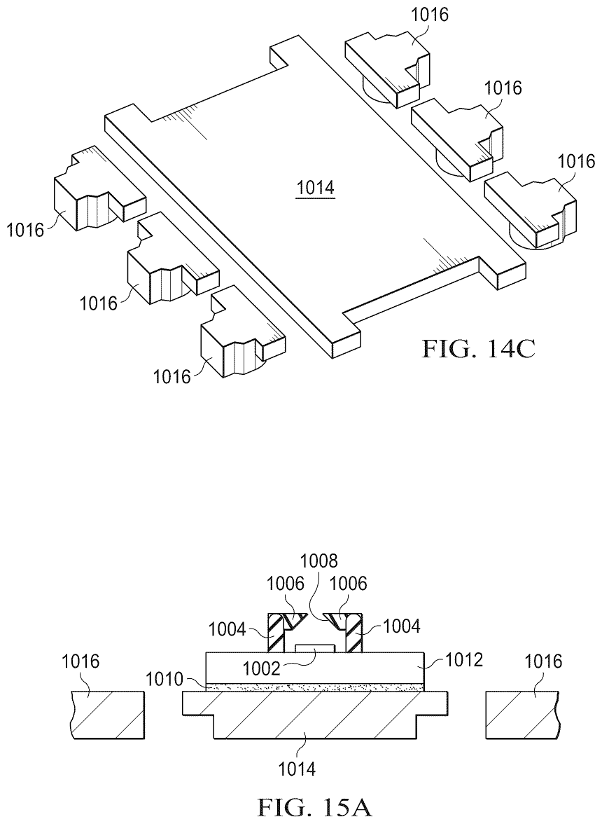

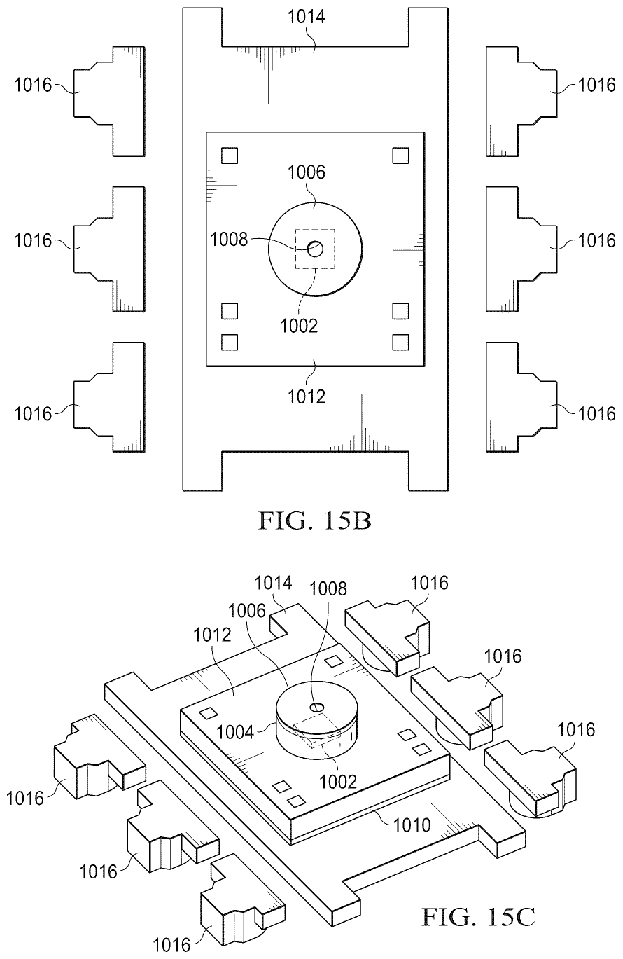

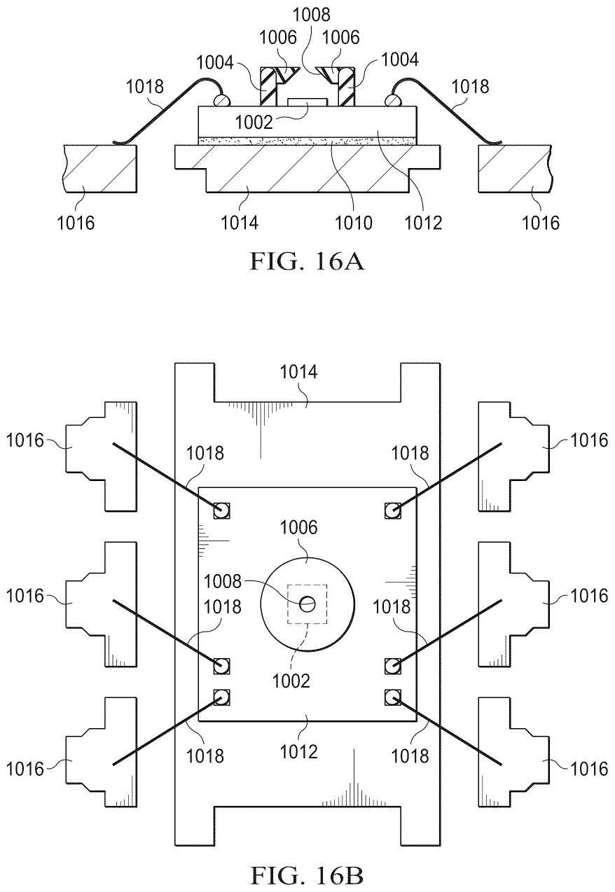

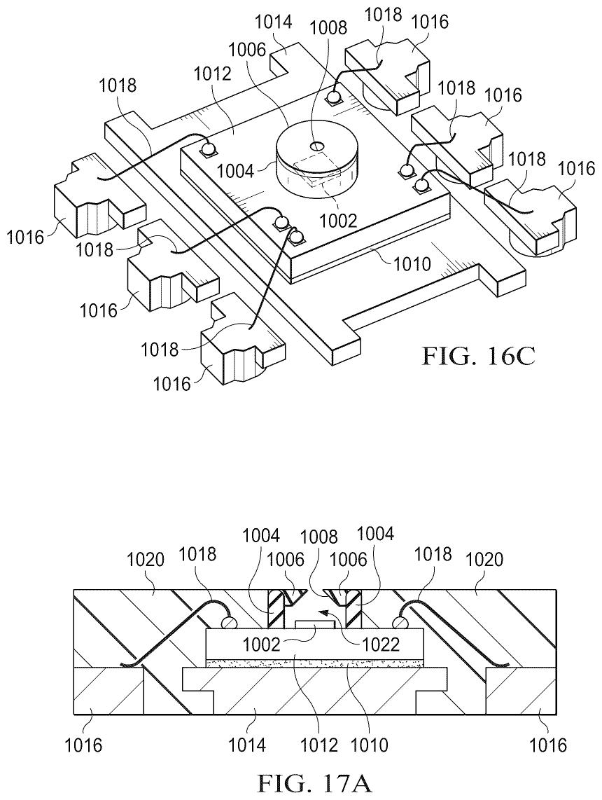

The method 100 may include coupling a semiconductor die to a die pad (106) and wire bonding the semiconductor die to a conductive terminal (108). In the process flow of FIGS. 2A-9, FIGS. 5A-C are cross-sectional, top-down, and perspective views, respectively, of a die pad 210 and multiple conductive terminals 212 (e.g., leads or pins). FIGS. 6A-C are cross-sectional, top-down, and perspective views, respectively, of one of the structures of FIGS. 4A-C coupled to the structure of FIGS. 5A-C, such as by using the die attach film 206. FIGS. 7A-C are cross-sectional, top-down, and perspective views, respectively, of the structure of FIGS. 6A-C, but with bond wires 214 coupled between the semiconductor die 208 and conductive terminals 212. In the process flow of FIGS. 10A-18, FIGS. 14A-C are cross-sectional, top-down, and perspective views, respectively, of a die pad 1014 and multiple conductive terminals 1016 (e.g., leads or pins). FIGS. 15A-C are cross-sectional, top-down, and perspective views, respectively, of one of the structures of FIGS. 13A-C coupled to the structure of FIGS. 14A-C, such as by using the die attach film 1010. FIGS. 16A-C are cross-sectional, top-down, and perspective views, respectively, of the structure of FIGS. 15A-C, but with bond wires 1018 coupled between the semiconductor die 1012 and conductive terminals 1016.

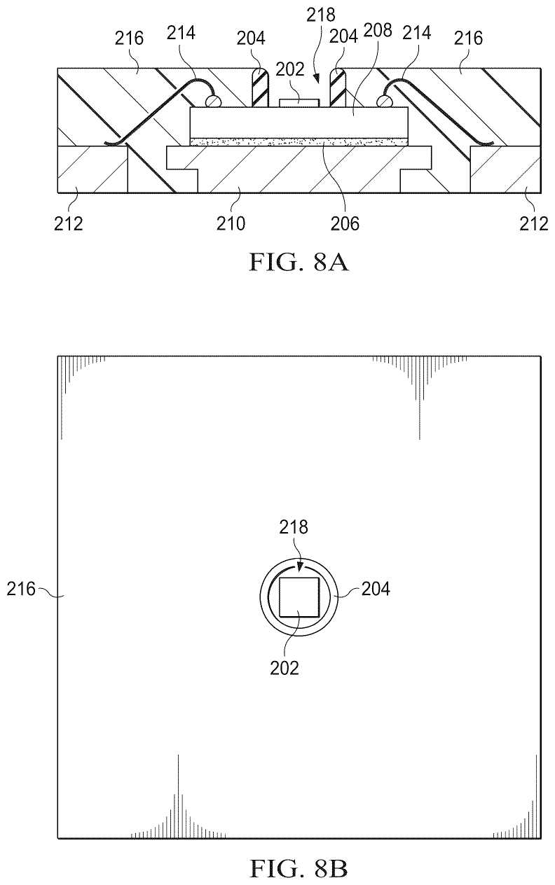

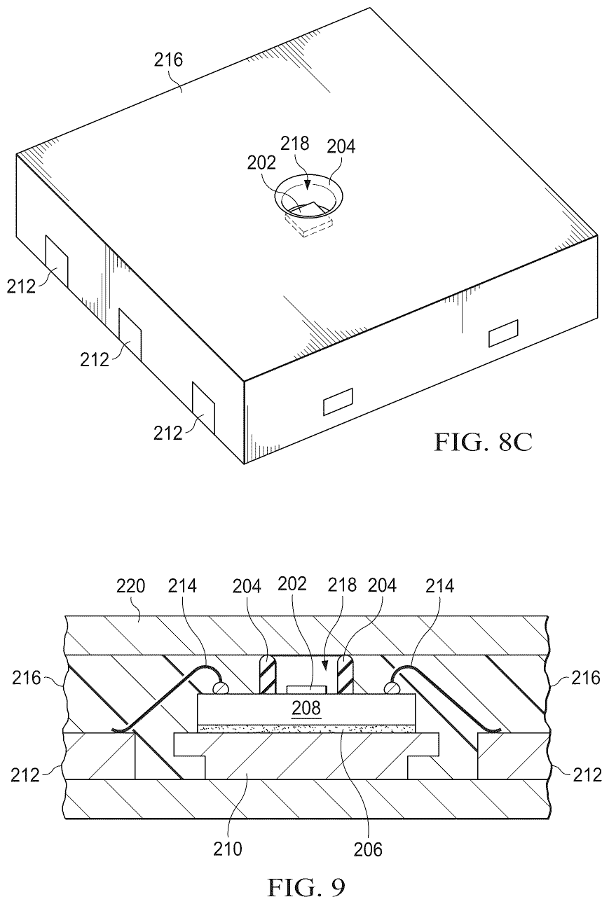

The method 100 may include covering the semiconductor die, the die pad, and the conductive terminal with a mold compound, with the mold compound dam precluding the mold compound from flowing into a cavity defined by the mold compound dam and precluding the mold compound from contacting the sensor (110). FIGS. 8A-C are cross-sectional, top-down, and perspective views, respectively, of the structure of FIGS. 7A-C, except with a mold compound 216 having been applied, and with the mold compound 216 defining a cavity 218 above the sensor 202. FIG. 9 depicts an example application of the mold compound 216. The structure of FIGS. 7A-C is positioned in a mold chase, and a mold chase lid 220 is lowered to contact the top surface of the mold compound dam 204, as shown. Mold compound 216 is then applied (e.g., by injection), but the mold compound dam 204 prevents the mold compound 216 from entering the cavity 218. In this way, the cavity 218 is formed to facilitate exposure of the sensor 202 to an ambient environment without using prior technology that results in undesirably large packages and/or physical damage to the semiconductor die 208 and/or sensor 202.

In the process flow of FIGS. 10A-18, FIGS. 17A-C are cross-sectional, top-down, and perspective views, respectively, of the structure of FIGS. 16A-C, except with a mold compound 1020 having been applied, and with the mold compound 1020 defining a cavity 1022 above the sensor 1002. FIG. 18 depicts an example application of the mold compound 1020. The structure of FIGS. 16A-C is positioned in a mold chase, and a mold chase lid 1024 is lowered to contact the top surface of the mold compound dam 1004, as shown. Mold compound 1020 is then applied (e.g., by injection), but the mold compound dam 1004 prevents the mold compound 1020 from entering the cavity 1022. In this way, the cavity 1022 is formed to facilitate exposure of the sensor 1002 to an ambient environment without using prior technology that results in undesirably large packages and/or physical damage to the semiconductor die 1012 and/or sensor 1002.

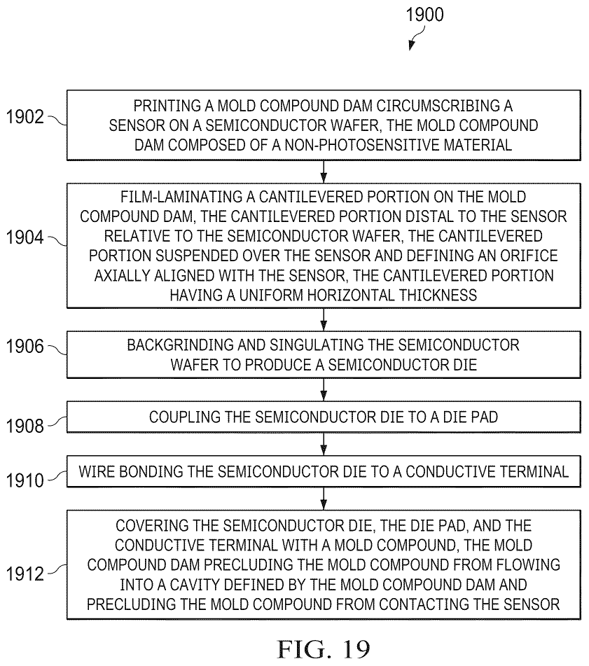

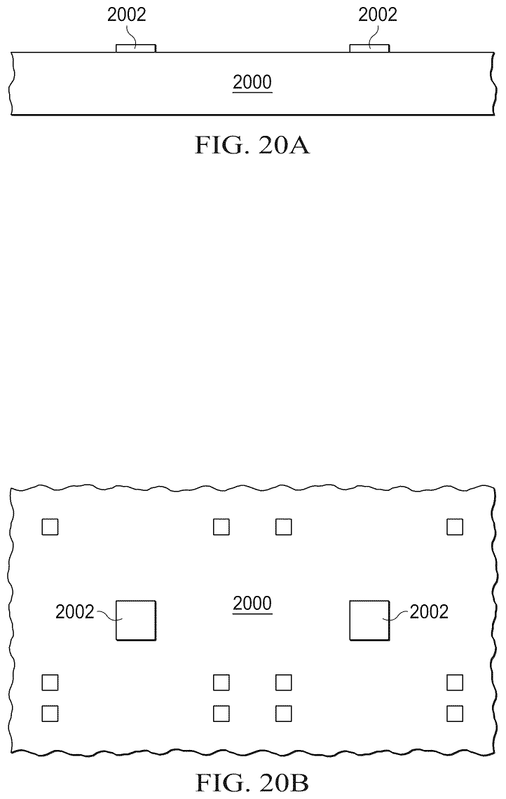

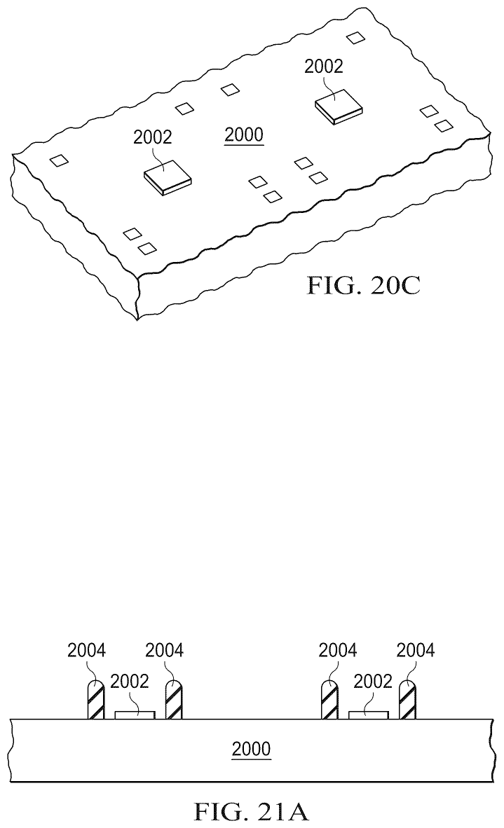

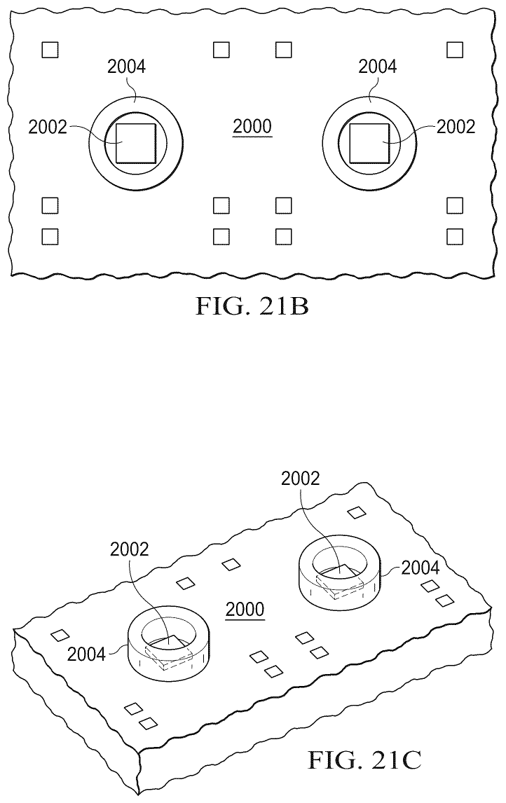

FIG. 19 is a flow diagram of a method 1900 for manufacturing a semiconductor package using a mold compound dam, in accordance with various examples. The method 1900 may include printing a mold compound dam circumscribing a sensor on a semiconductor wafer, where the mold compound dam is composed of a non-metallic material (1902). FIGS. 20A-C are cross-sectional, top-down, and perspective views of a semiconductor wafer 2000 and sensors 2002 on the semiconductor wafer 2000. FIGS. 21A-C are cross-sectional, top-down, and perspective views of the structure of FIGS. 20A-C, except that mold compound dams 2004 are provided on the semiconductor wafer 2000, each mold compound dam 2004 circumscribing a different sensor 2002. The description provided herein for mold compound dams 204 also may apply, in whole or in part, to the mold compound dams 2004. The mold compound dams 2004 may be composed of any non-metallic material that is photosensitive or non-photosensitive, such as polyimide, PBO, any suitable polymer, ink, or epoxy (e.g., SU-8), for example. In examples, the mold compound dams 2004 are printed on the semiconductor wafer 2000, such as by inkjet printing, stencil printing, nano imprinting, any suitable additive manufacturing process, or any other suitable process. The physical features of the mold compound dams 2004 may be similar or identical to those described above for the mold compound dams 204 and/or 1004.

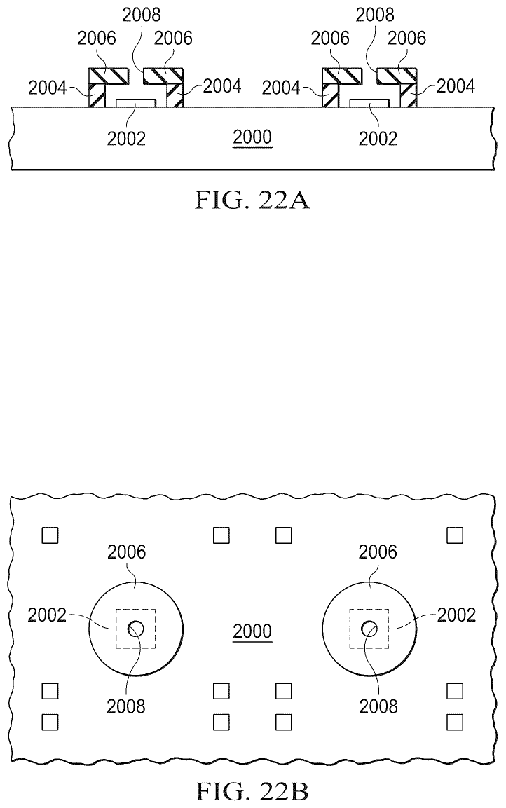

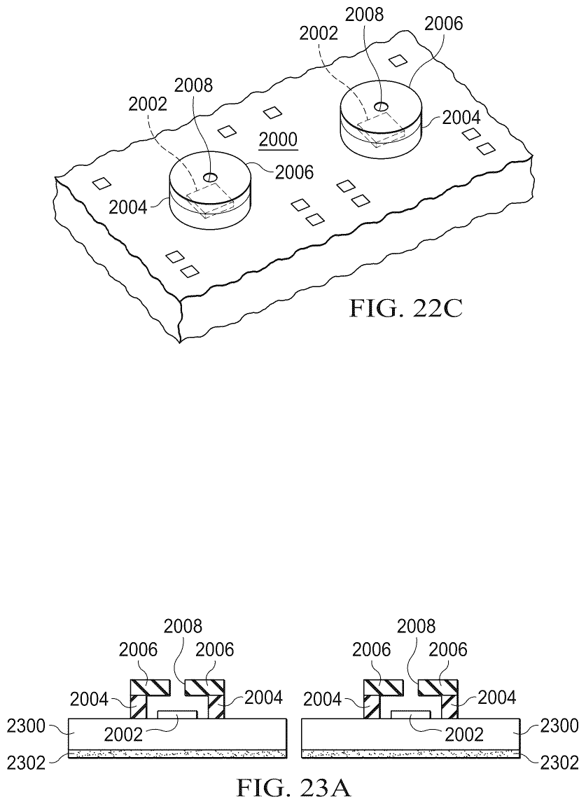

The method 1900 may include film-laminating a cantilevered portion on the mold compound dam (1904). The cantilevered portion may be distal to the sensor (relative to the semiconductor wafer) and may be suspended over the sensor (1904). The cantilevered portion may define an orifice axially aligned with the sensor, with the cantilevered portion having a uniform horizontal thickness (as measured from an outer surface of the cantilevered portion to an inner surface of the cantilevered portion) from a top surface of the cantilevered portion to a bottom surface of the cantilevered portion and a uniform vertical thickness (as measured from a top surface of the cantilevered portion to a bottom surface of the cantilevered portion) from an outer surface of the cantilevered portion to an inner surface of the cantilevered portion (1904). FIGS. 22A-C are cross-sectional, top-down, and perspective views of the structure of FIGS. 21A-C, except that a cantilevered portion 2006 has been applied to each of the mold compound dams 2004, as shown. The cantilevered portion 2006 may have an approximately uniform vertical thickness from the outer perimeter of the cantilevered portion 2006 to the portion of the cantilevered portion 2006 most proximal to an orifice 2008, and a uniform horizontal thickness (as measured between inner and outer surfaces of the cantilevered portion 2006) from a top surface of the cantilevered portion 2006 to a bottom surface of the cantilevered portion 2006. The orifice 2008 is axially aligned with a respective sensor 2002, as shown, meaning that a line extending vertically orthogonal to the sensor 2002 will extend through the orifice 2008. The cantilevered portion 2006 may be formed using any suitable technique, such as a film lamination technique. If a film lamination technique is used, the film must be adequately rigid to avoid bowing or dipping into the cavity below the cantilevered portion 2006. Accordingly, the rigidity of the cantilevered portion 2006 is at least 1 GPa, with a rigidity below this threshold leading to unacceptable bowing or dipping into the cavity below the cantilevered portion 2006. The diameter of the orifice 2008 ranges from 30 microns to 1000 microns, with a diameter below this range being disadvantageous because of decreased sensing accuracy, and with a diameter above this range being disadvantageous because of the risk of sensor contamination. As shown, the cantilevered portion 2006 is suspended over the sensor 2002, and the orifice 2008 is axially aligned with the sensor 2002 such that a line extending orthogonally through the sensor 2002 also extends through the orifice 2008.

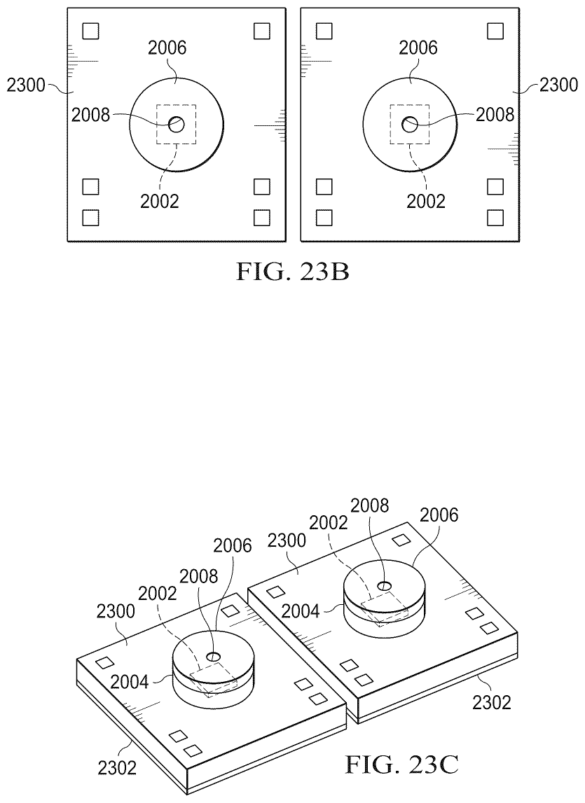

The method 1900 includes backgrinding and singulating the semiconductor wafer to produce a semiconductor die (1906). FIGS. 23A-C are cross-sectional, top-down, and perspective views of the structure of FIGS. 22A-C, except that the wafer 2000 has been thinned by backgrinding and has been singulated, such as by mechanical saw. The result is multiple semiconductor dies 2300, as shown. The semiconductor dies 2300 may have backsides to which a die attach material 2302 is coupled.

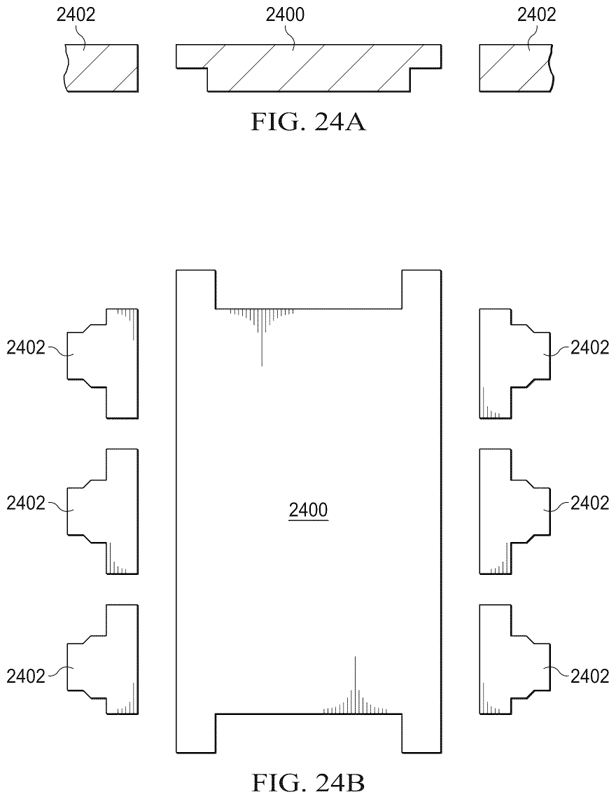

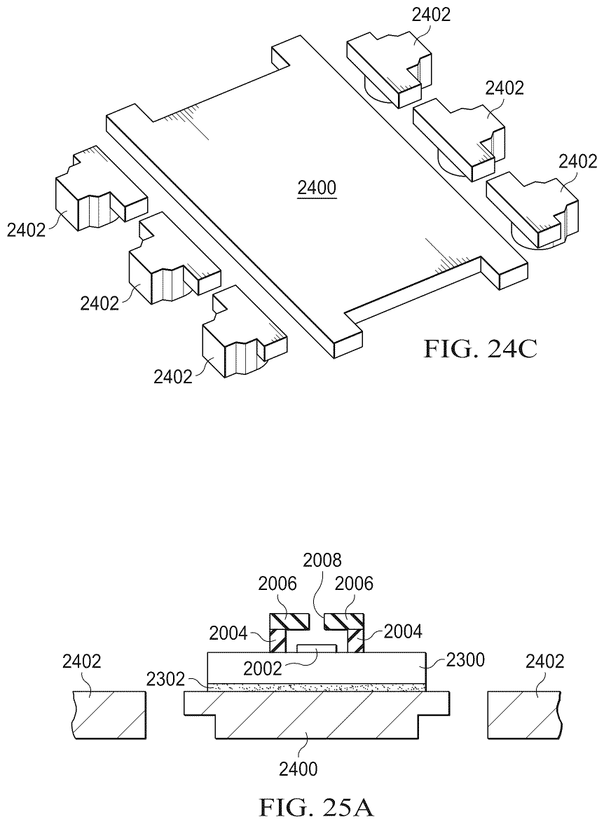

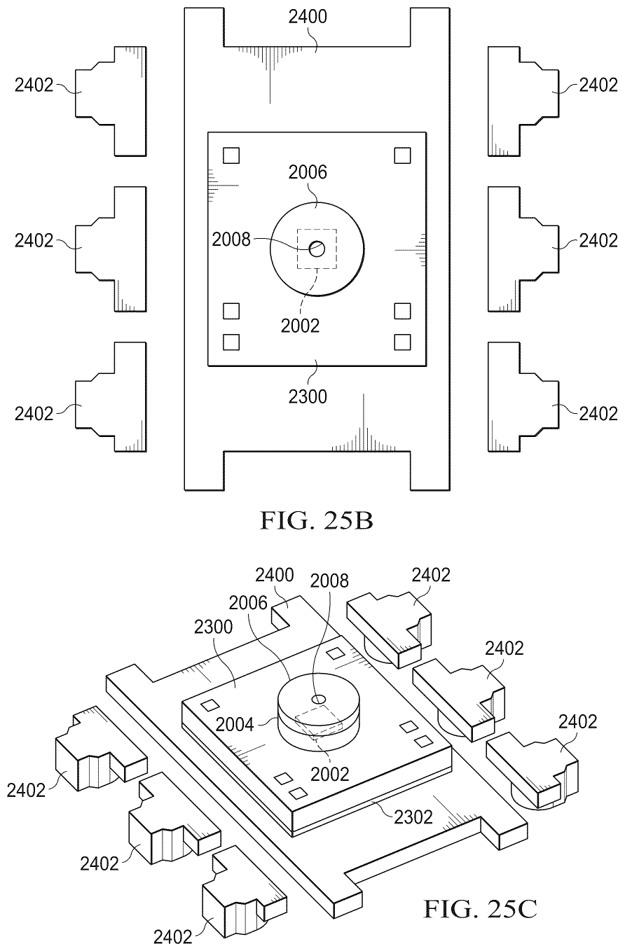

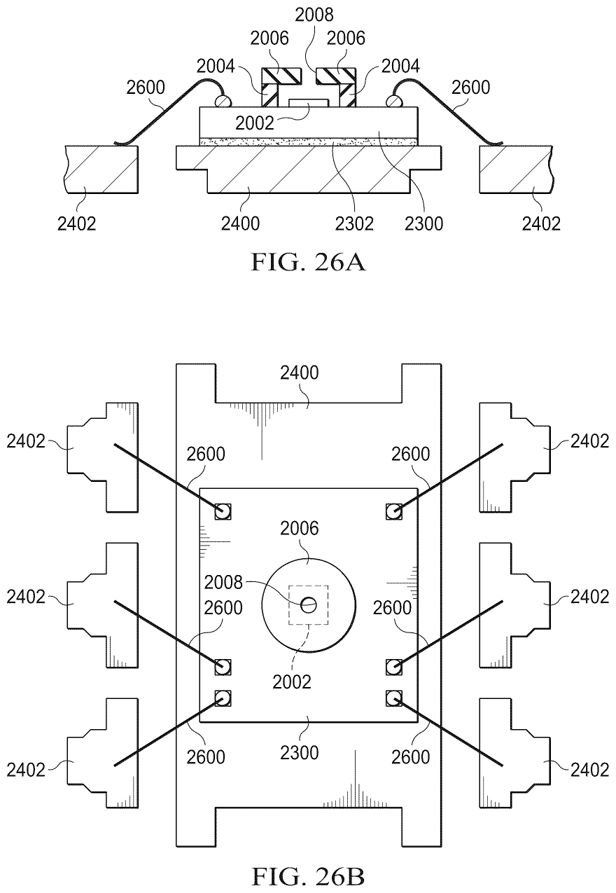

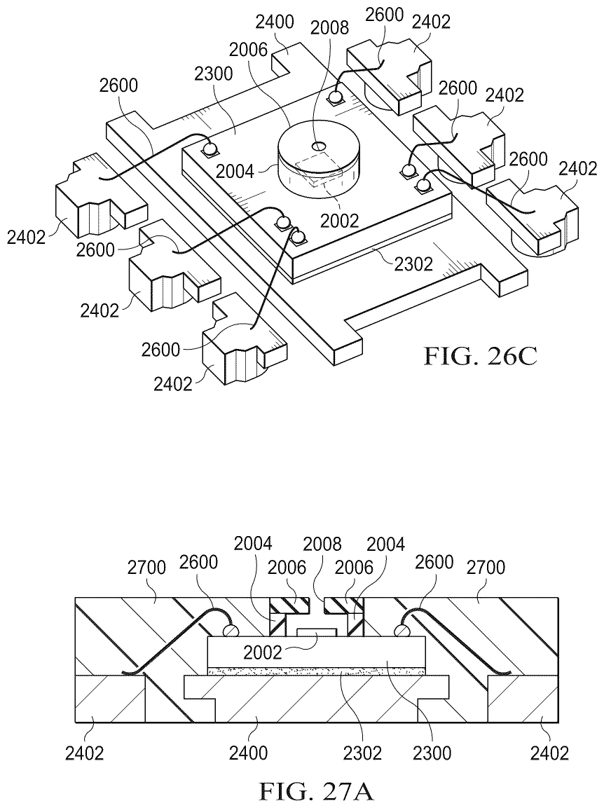

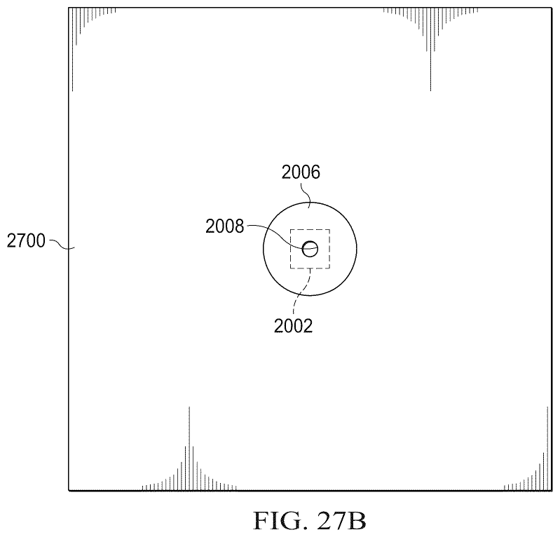

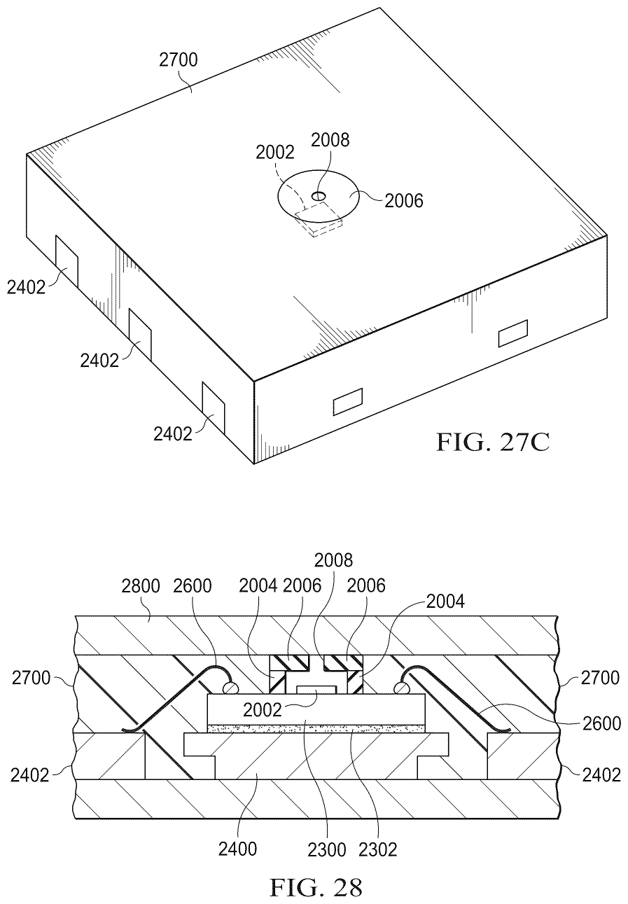

The method 1900 includes coupling the semiconductor die to a die pad (1908), wire bonding the semiconductor die to a conductive terminal (1910), and covering the semiconductor die, the die pad, and the conductive terminal with a mold compound (1912). The mold compound dam precludes the mold compound from flowing into a cavity defined by the mold compound dam (including the cantilevered portion of the mold compound dam) and precludes the mold compound from contacting the sensor in the cavity (1912). FIGS. 24A-C are cross-sectional, top-down, and perspective views of a die pad 2400 and conductive terminals 2402. In the cross-sectional, top-down, and perspective views of FIGS. 25A-C, one of the structures shown in FIG. 23 (i.e., a semiconductor die 2300 with a respective mold compound dam 2004 and sensor 2002) is coupled to the die pad 2400 by the die attach material 2302. In FIGS. 26A-C, the structure of FIGS. 25A-C is shown including bond wires 2600 extending from the semiconductor die 2300 to the conductive terminals 2402. In FIGS. 27A-C, a mold compound 2700 is applied to cover the various structures shown in FIGS. 26A-C, except that the mold compound 2700 does not enter the orifice 2008 or the cavity defined by the mold compound dam 2004. Similar to the various other examples described herein, the mold compound 2700 does not cover the top surface of the mold compound dam 2004. FIG. 28 depicts a mold chase lid 2800, together with the mold compound dam 2004, preventing the mold compound 2700 from entering the orifice 2008.

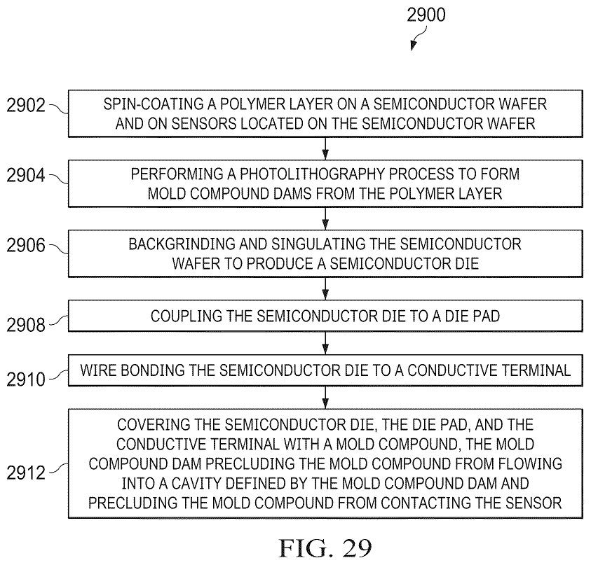

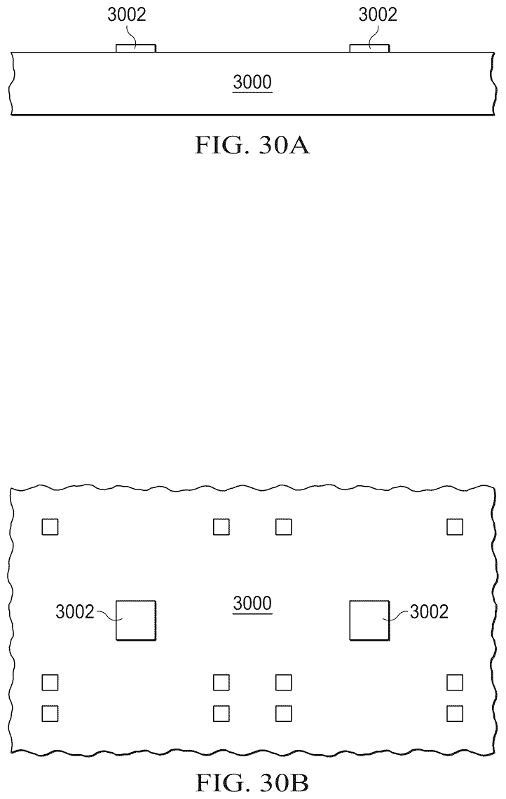

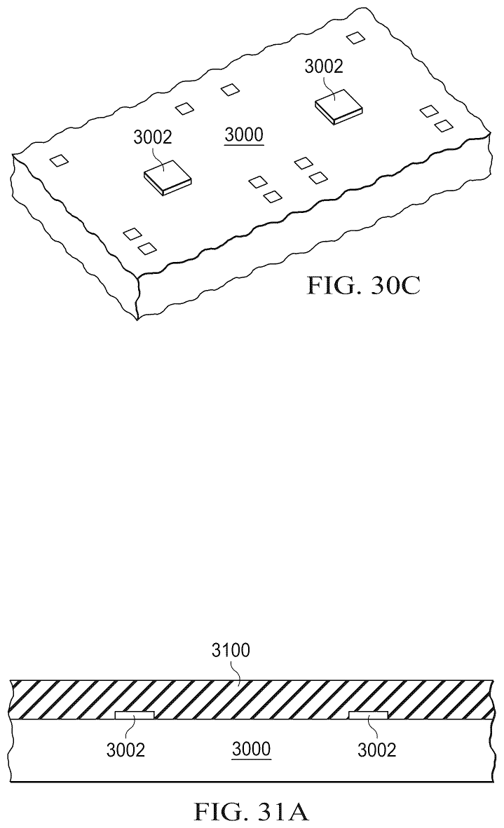

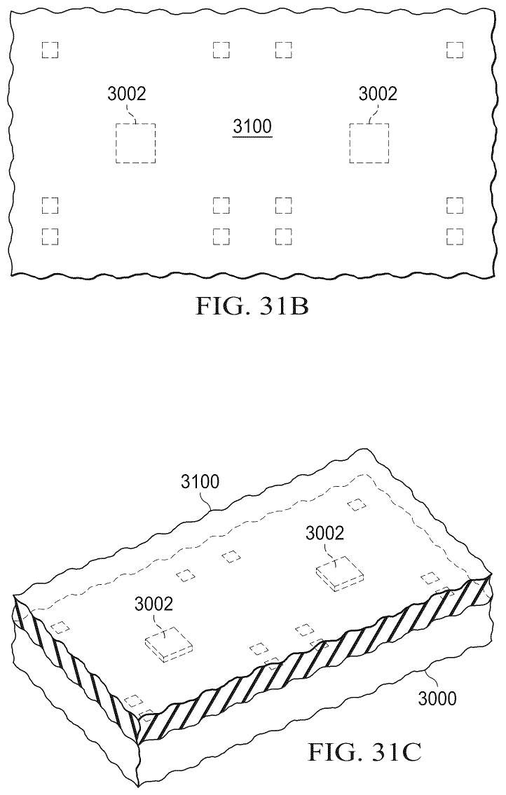

FIG. 29 is a flow diagram of a method 2900 for manufacturing a semiconductor package using a mold compound dam, in accordance with various examples. The method 2900 may include spin-coating a polymer layer on a semiconductor wafer and on sensors located on the semiconductor wafer (2902). FIGS. 30A-C depict cross-sectional, top-down, and perspective views of a semiconductor wafer 3000 (e.g., silicon, silicon carbide, gallium arsenide, or gallium nitride wafer) and sensors 3002 on the wafer 3000. FIGS. 31A-C depict cross-sectional, top-down, and perspective views of the structure of FIGS. 30A-C, except with a spin-coated polymer layer 3100 on the device side of the wafer 3000 and on the sensors 3002. Other application techniques for the polymer layer 3100 are contemplated and included in the scope of this disclosure.

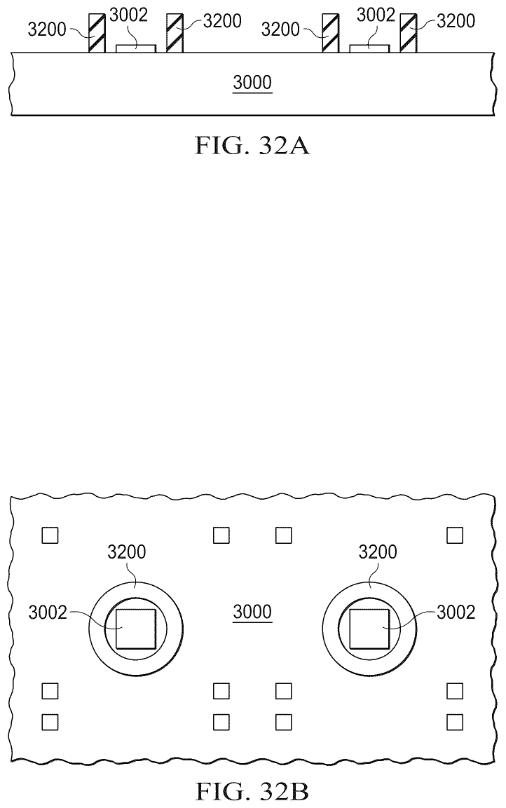

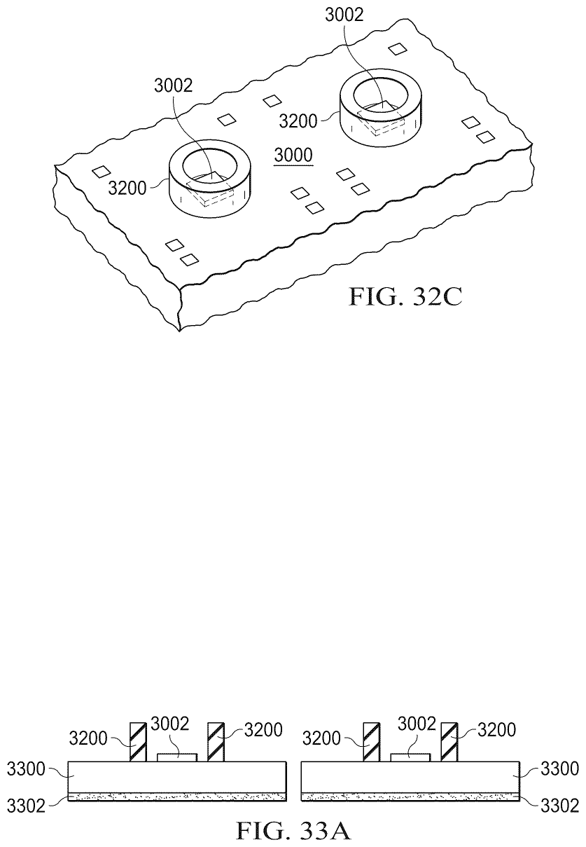

The method 2900 may include performing a photolithography process to form mold compound dams from the spin-coated polymer layer (2904). FIGS. 32A-C show the structure of FIGS. 31A-C, except that a photolithographic process has been performed to form mold compound dams 3200 from the polymer layer 3100. Such a photolithographic process may include, for example, the use of appropriately patterned masks, light exposure, developing fluid, etc. to pattern the polymer layer 3100. Other techniques for patterning the polymer layer 3100 are contemplated and included in the scope of this disclosure. The mold compound dams 3200 may have a cylindrical shape, for example, although other shapes are contemplated and included in the scope of this disclosure. The description provided herein for the mold compound dams 204 also may be applied, in whole or in part, to the mold compound dams 3200.

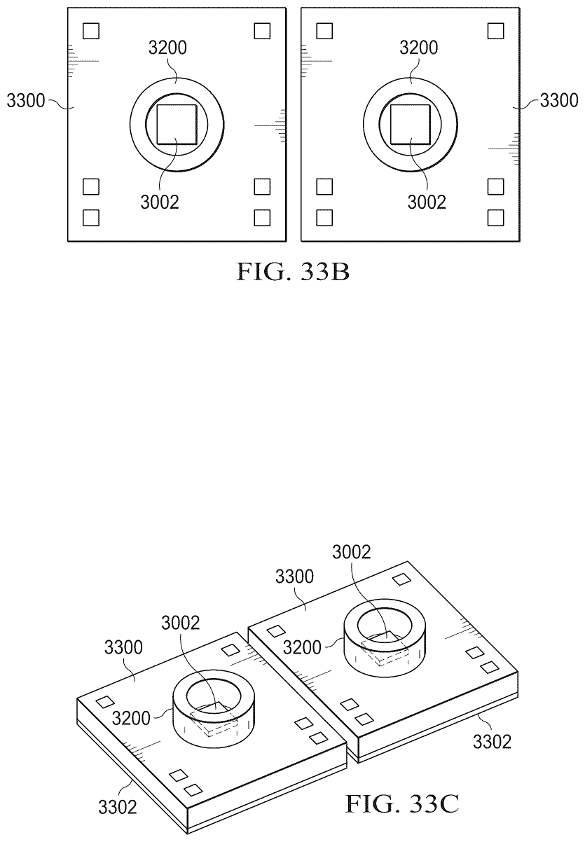

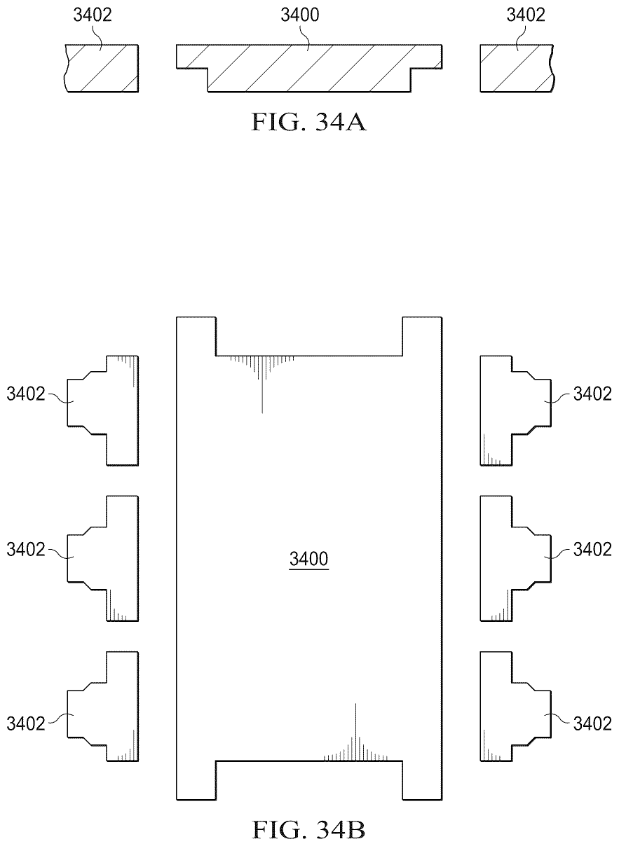

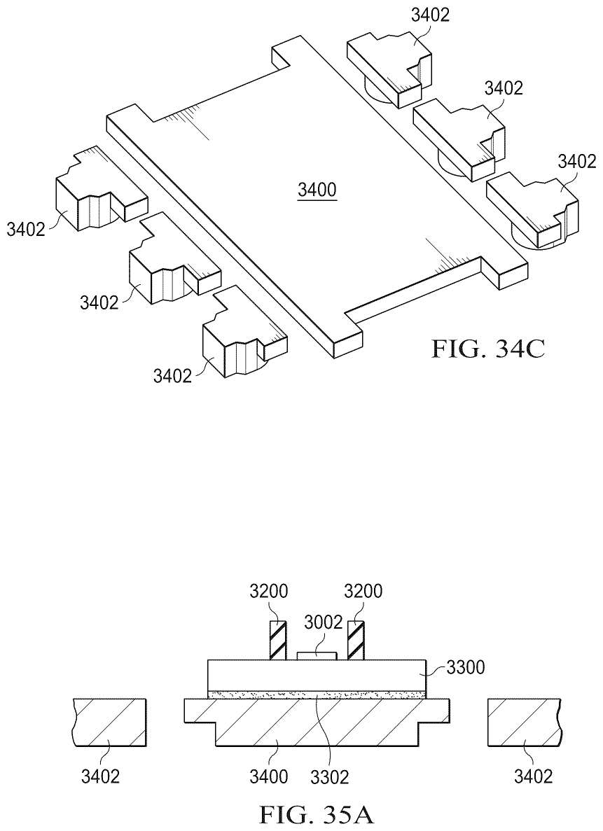

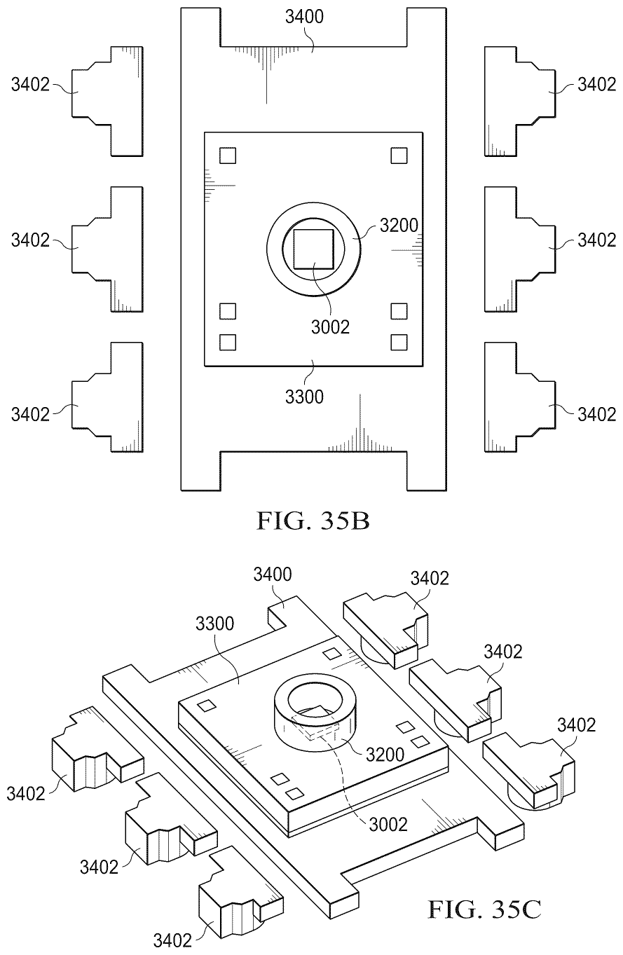

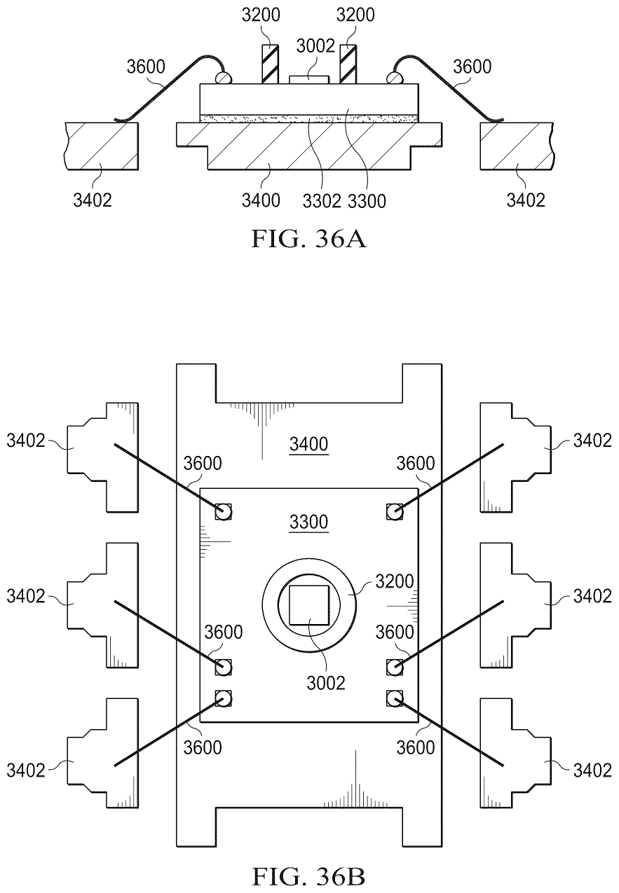

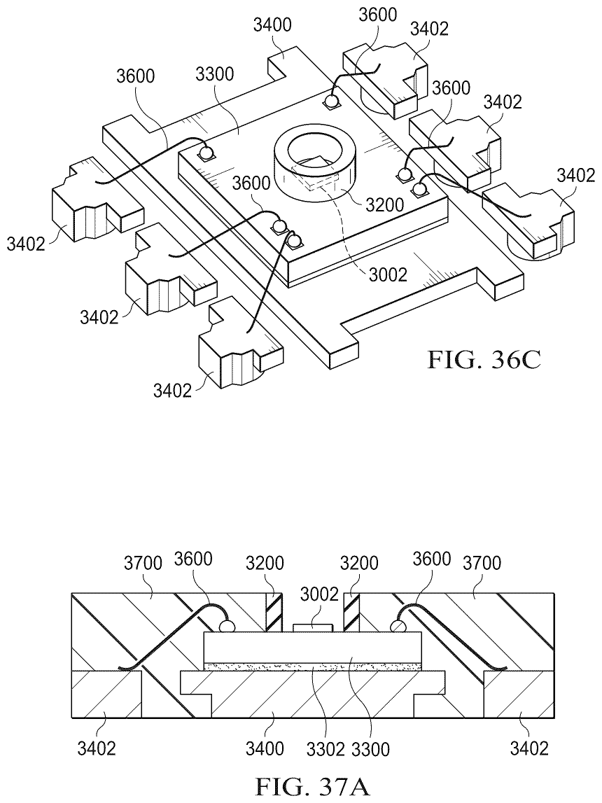

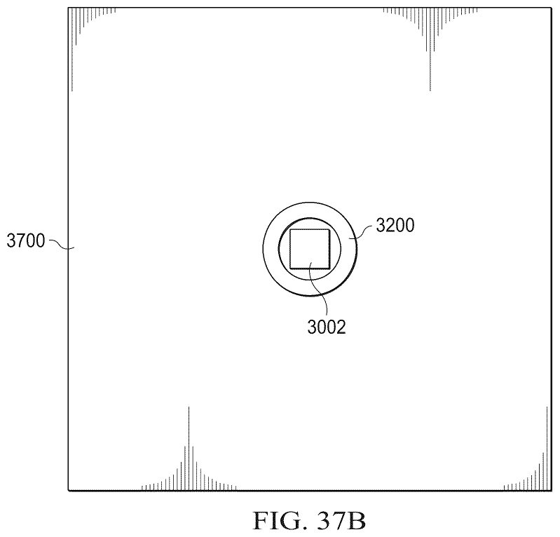

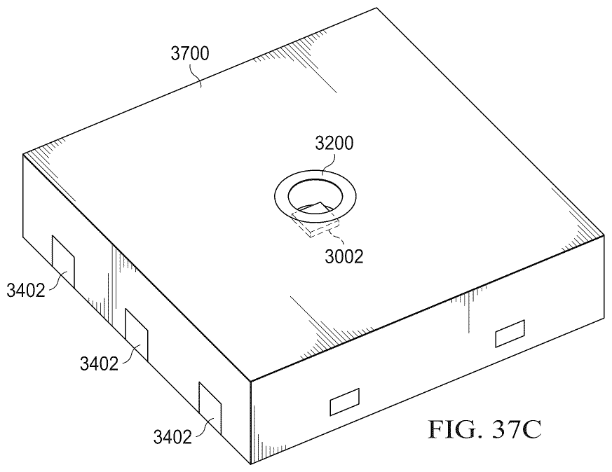

The method 2900 may include backgrinding and singulating the semiconductor wafer to produce a semiconductor die (2906), coupling the semiconductor die to a die pad (2908), wire bonding the semiconductor die to a conductive terminal (2910), and covering the semiconductor die, the die pad, and the conductive terminal with a mold compound (2912). The mold compound dam precludes the mold compound from flowing into a cavity defined by the mold compound dam and precludes the mold compound from contacting the sensor (2912). FIGS. 33A-C are cross-sectional, top-down, and perspective views of the structure of FIGS. 32A-C, except that the wafer 3000 has been thinned by backgrinding, and the wafer 3000 has been singulated, such as by a mechanical saw, to produce individual semiconductor dies 3300. Die attach material 3302 may be applied to the non-device sides of the semiconductor dies 3300. FIGS. 34A-C are cross-sectional, top-down, and perspective views of a die pad 3400 and conductive terminals 3402. FIGS. 35A-C are cross-sectional, top-down, and perspective views of one of the structures of FIGS. 33A-C (i.e., a semiconductor die 3300, a respective sensor 3002, a respective mold compound dam 3200, and a respective die attach material 3302) being coupled to the die pad 3400. In the cross-sectional, top-down, and perspective views of FIGS. 36A-C, bond wires 3600 are coupled to the semiconductor die 3300 and to the conductive terminals 3402. FIGS. 37A-C are cross-sectional, top-down, and perspective views of the structure of FIGS. 36A-C, but with the mold compound 3700 applied. The mold compound dam 3200 precludes the mold compound 3700 from entering the cavity above the sensor 3002 and defined by the mold compound dam 3200.

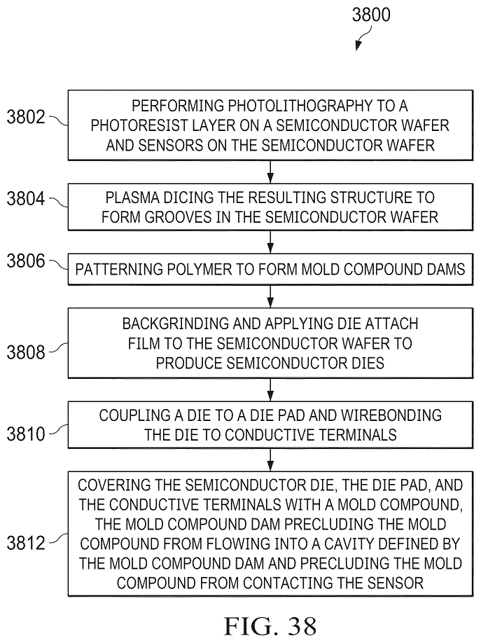

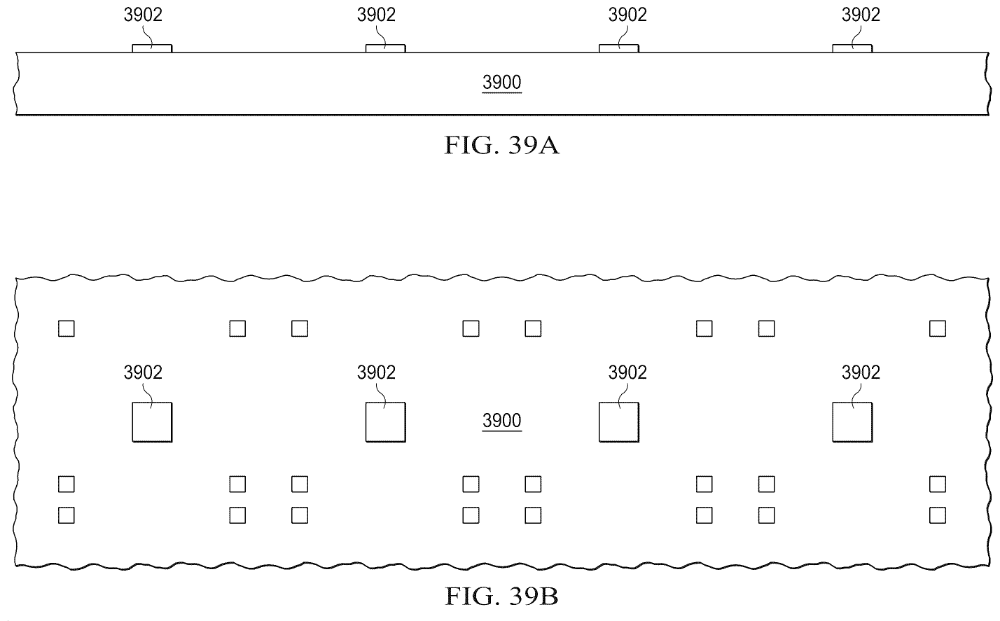

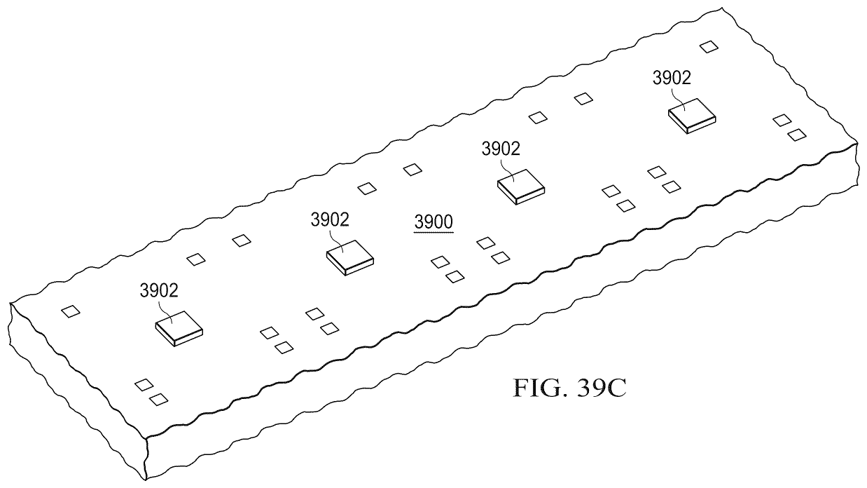

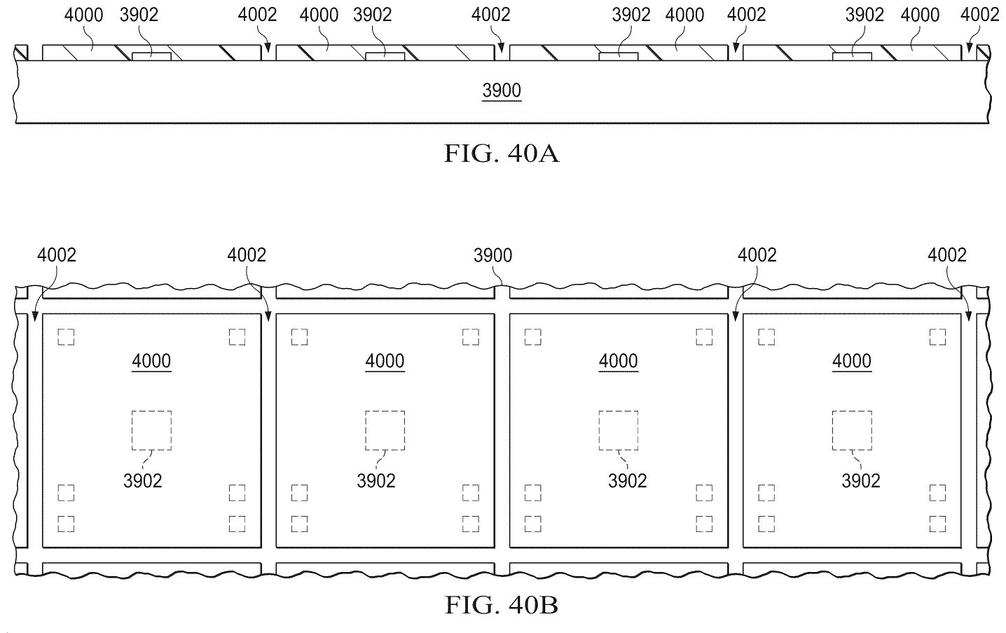

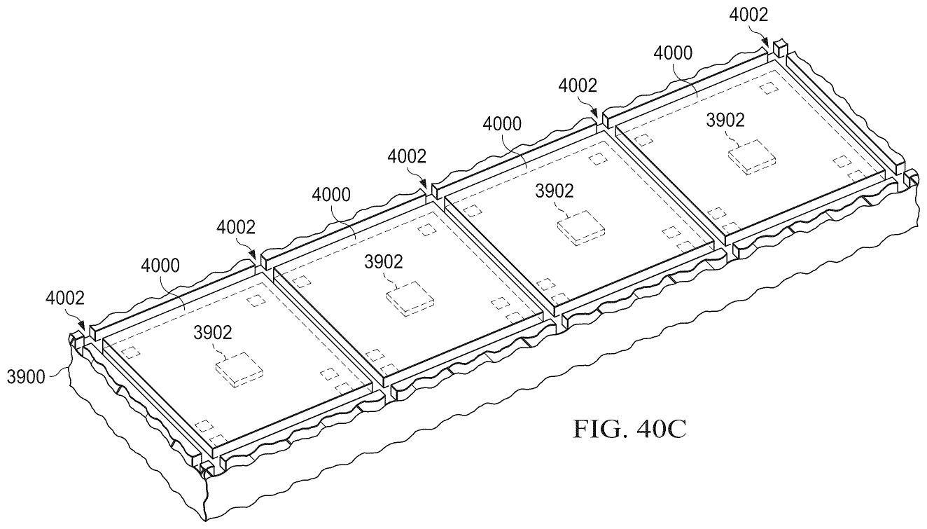

FIG. 38 is a flow diagram of a method 3800 for manufacturing a semiconductor package using a mold compound dam, in accordance with various examples. The method 3800 comprises performing photolithography to a photoresist layer on a semiconductor wafer and sensors on the semiconductor wafer (3802). FIGS. 39A-C are cross-sectional, top-down, and perspective views of a semiconductor wafer 3900 (e.g., silicon, silicon carbide, gallium arsenide, gallium nitride) on which sensors 3902 are positioned. FIGS. 40A-C are cross-sectional, top-down, and perspective views of the structure of FIGS. 39A-C, except that a layer of photoresist 4000 has been applied to the device side of the wafer 3900, and the layer of photoresist 4000 has been subjected to a photolithographic process (e.g., using an appropriately patterned mask, light exposure, developing solution, etc.) to pattern the layer of photoresist 4000. In examples, the photoresist 4000 is patterned to create longitudinal grooves 4002 in the photoresist 4000 between the sensors 3902, as shown.

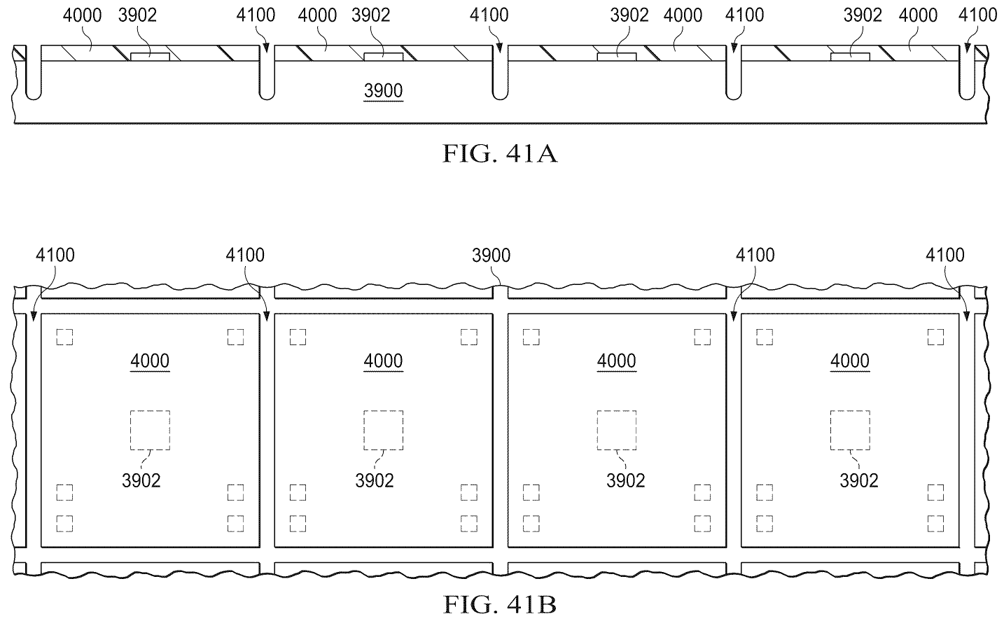

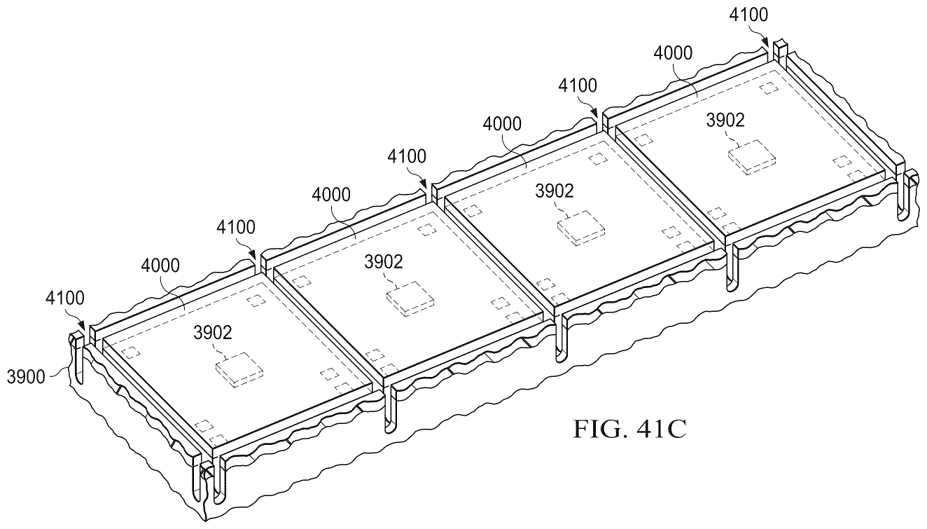

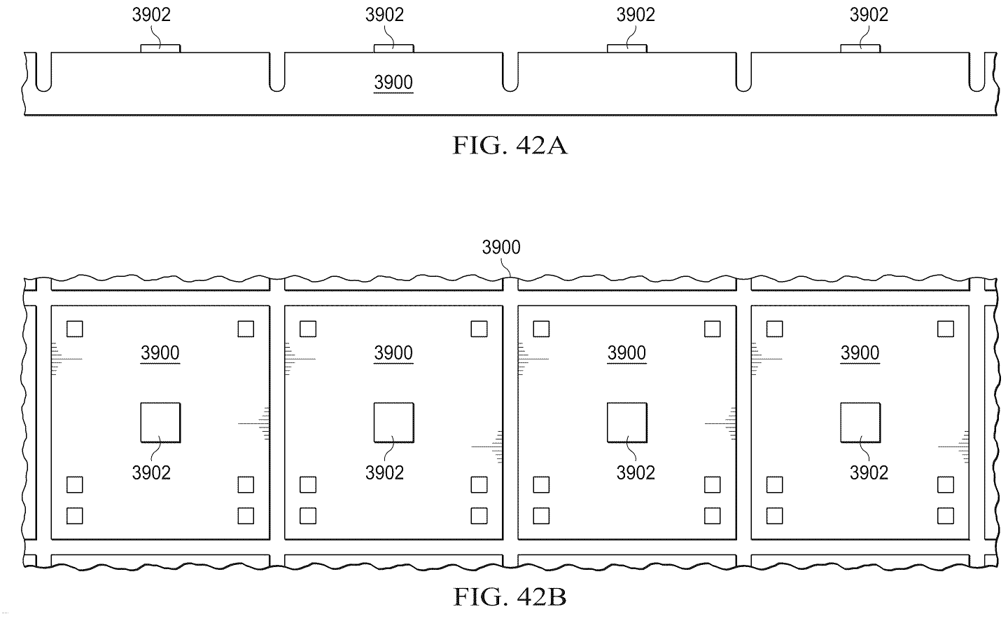

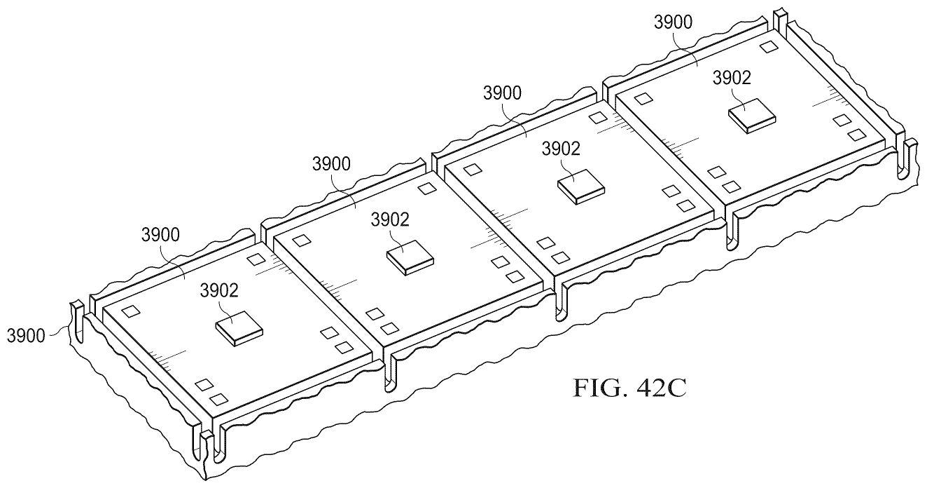

The method 3800 includes plasma dicing the resulting structure to form grooves in the semiconductor wafer (3804). FIGS. 41A-C are cross-sectional, top-down, and perspective views of the structure of FIGS. 40A-C, except that a plasma dicing technique has been used to form grooves 4100 in the wafer 3900, using the grooves 4002 in the photoresist 4000. The grooves 4100 extend sufficiently deep into the wafer 3900 such that subsequent backgrinding to thin the wafer 3900 will result in singulation of the wafer 3900. FIGS. 42A-C show that the photoresist 4000 is removed.

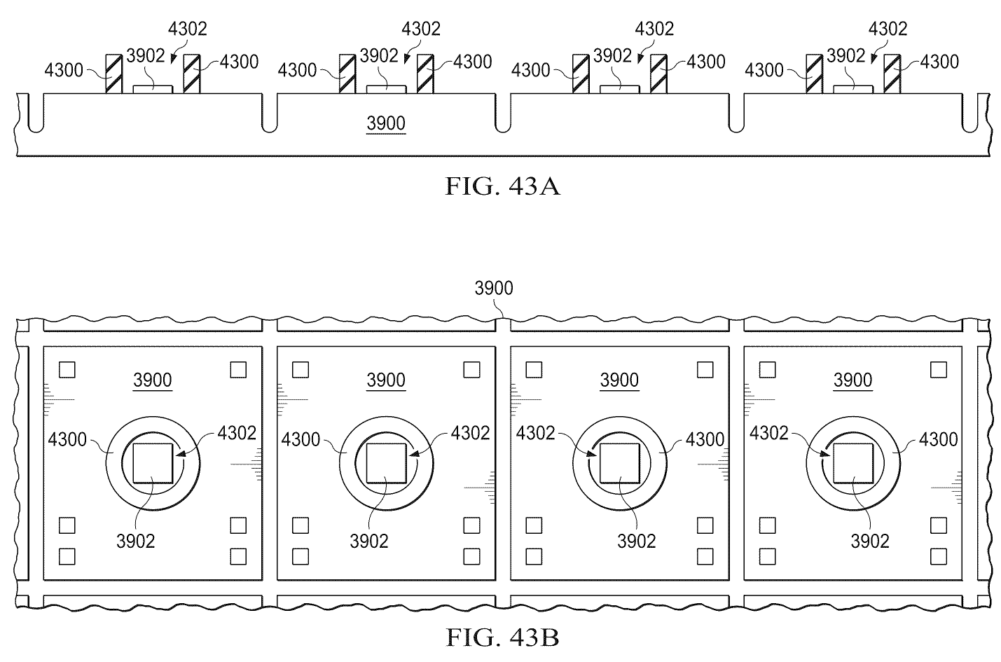

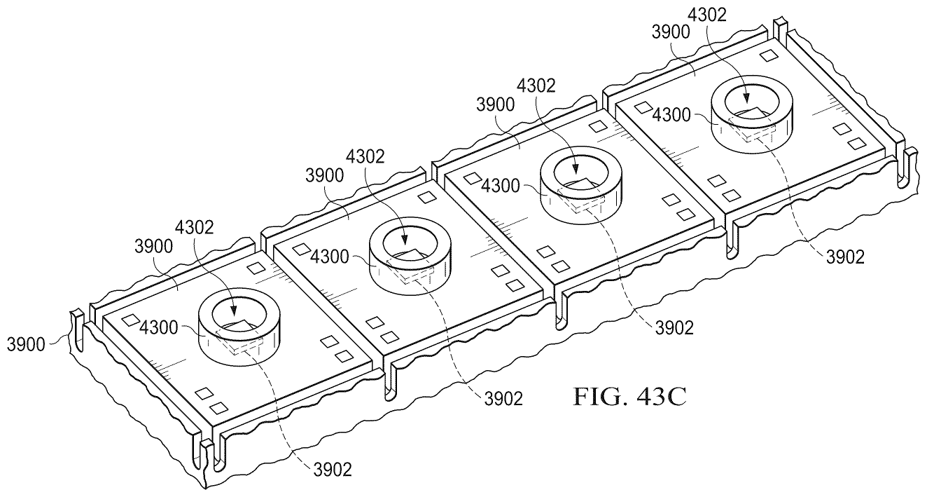

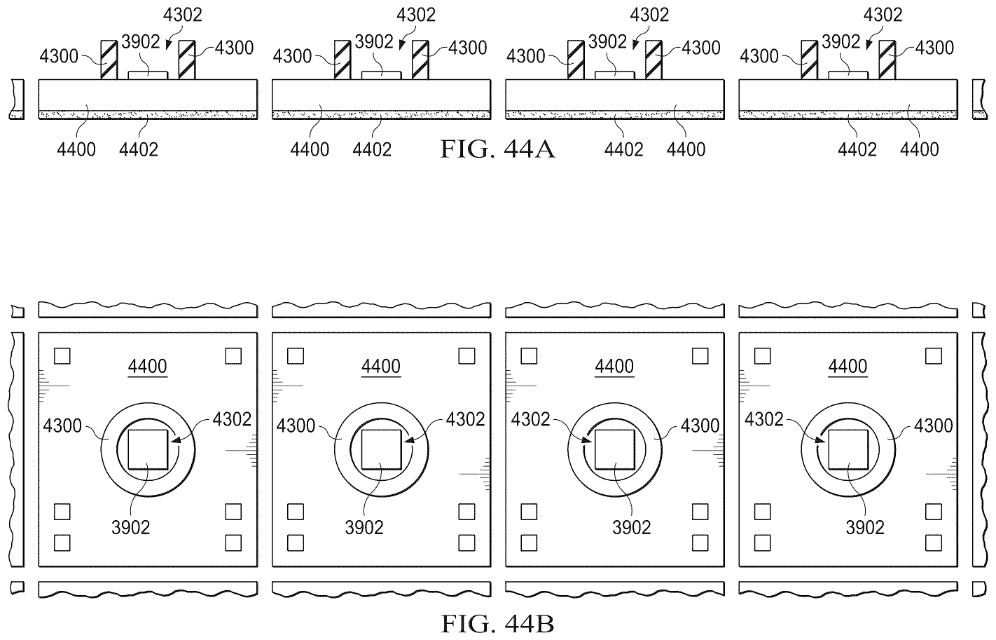

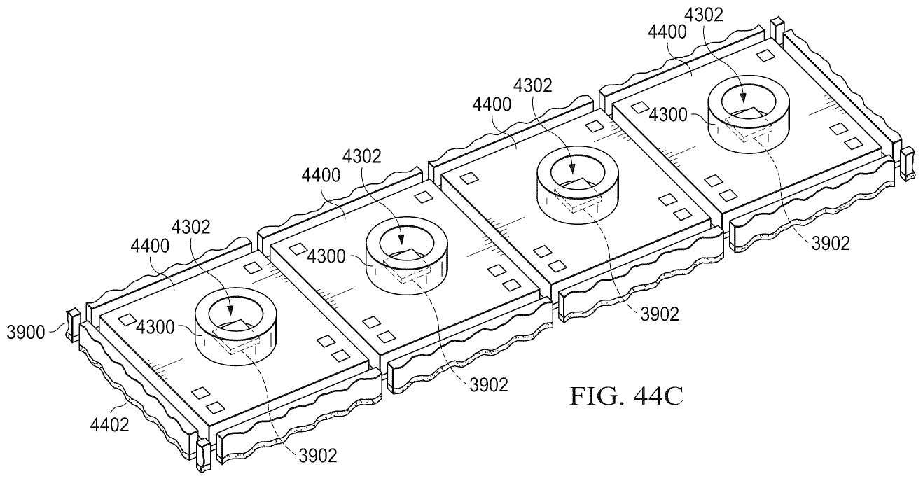

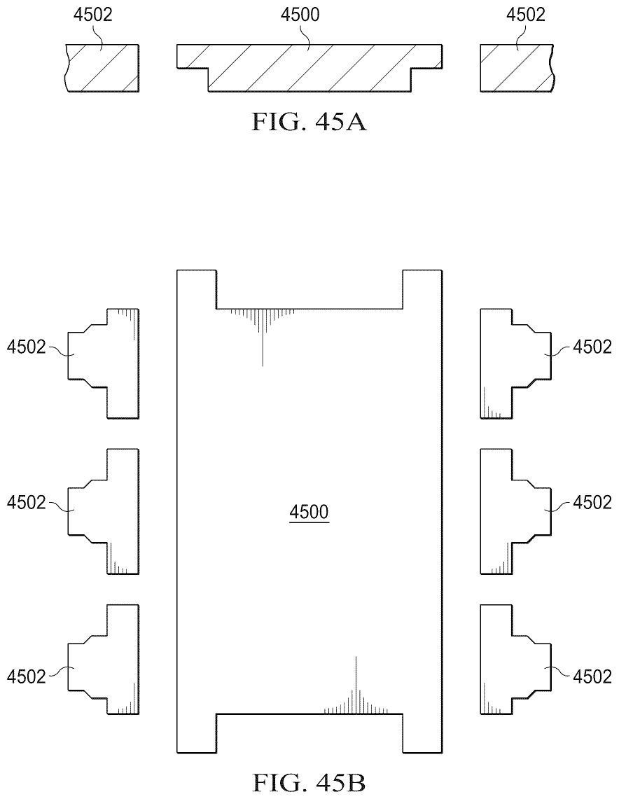

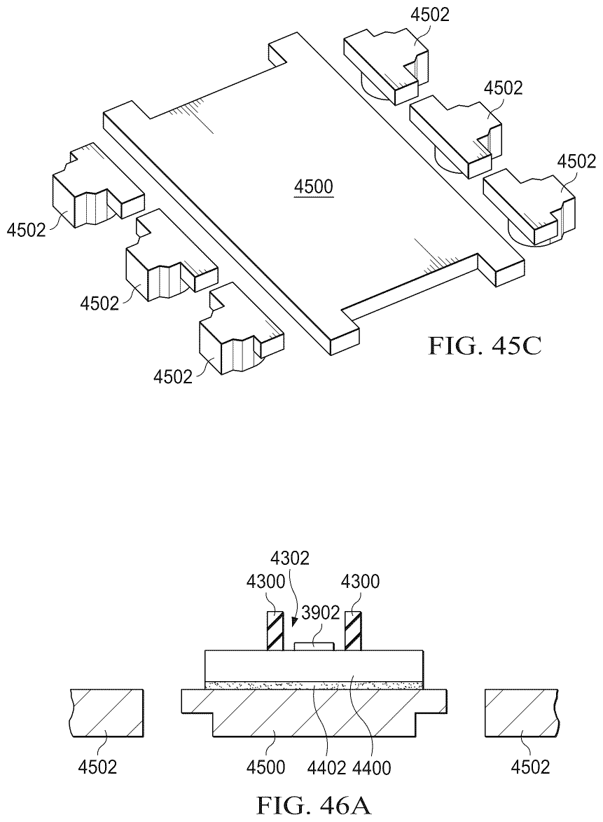

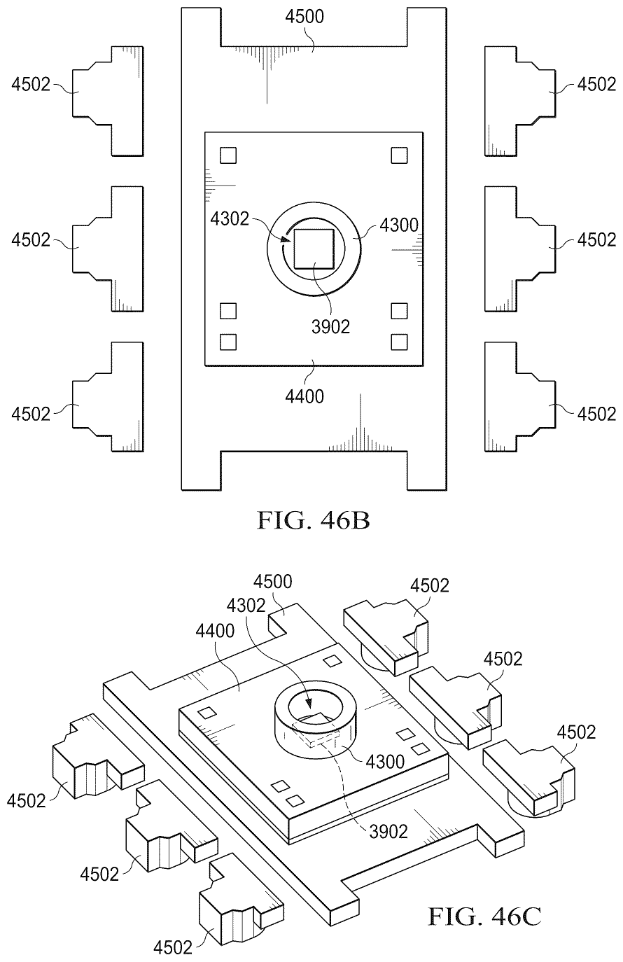

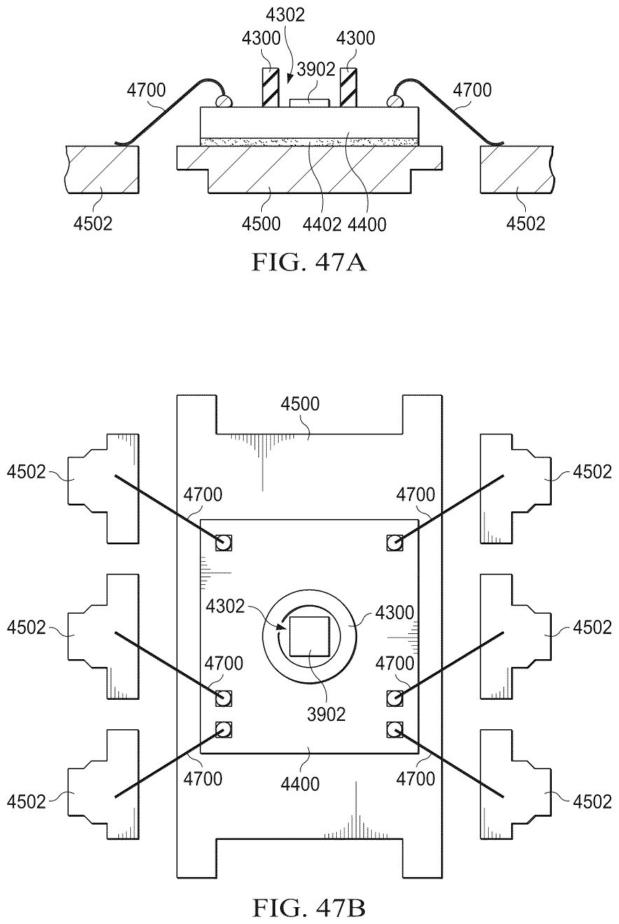

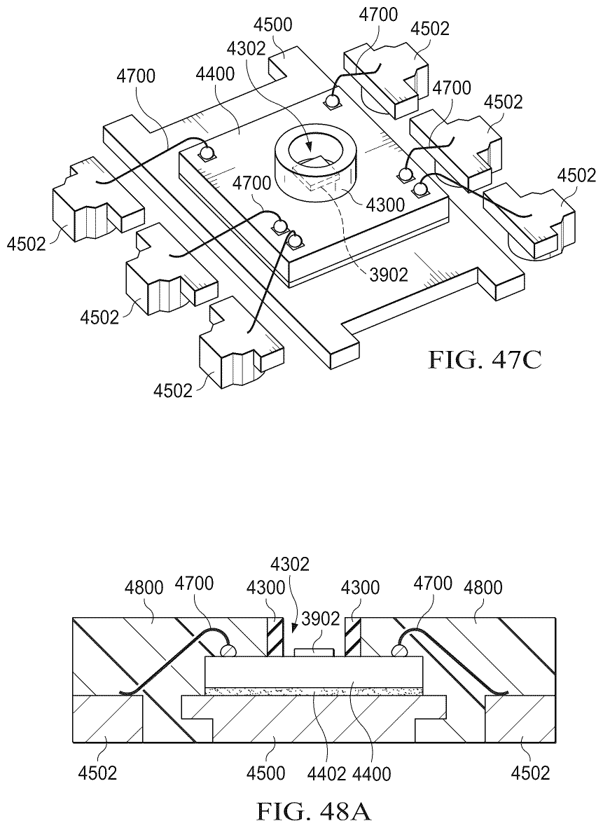

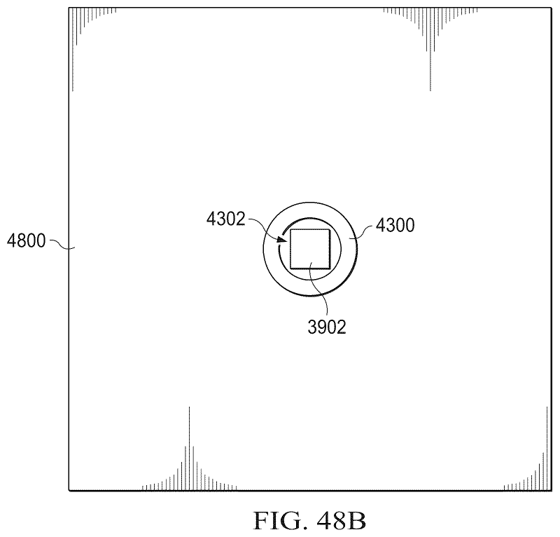

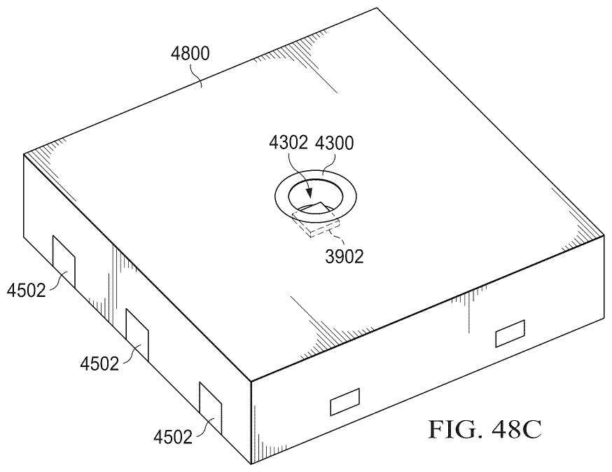

The method 3800 includes patterning a polymer layer to form mold compound dams (3806). FIGS. 43A-C are cross-sectional, top-down, and perspective views of the structure of FIGS. 42A-C, except that a polymer layer has been patterned (e.g., using photolithography) to form the mold compound dams 4300. The mold compound dams 4300 may have similar physical features, in whole or in part, as the various other mold compound dams 4300 described herein, such as the mold compound dams 204. For example, the mold compound dams 4300 may be cylindrical structures defining cavities 4302 in which the sensors 3902 are located, as shown. The method 3800 includes backgrinding the semiconductor wafer to produce individual semiconductor dies (3808), applying die attach film to the dies (3808), coupling a die to a die pad and wire bonding the die to conductive terminals (3810), and covering the semiconductor die, the die pad, and the conductive terminals with a mold compound (3812). The mold compound dam precludes the mold compound from flowing into a cavity defined by the mold compound dam and precludes the mold compound form contacting the sensor (3812). FIGS. 44A-C are cross-sectional, top-down, and perspective views of the structure of FIGS. 43A-C, except that the wafer 3900 has been thinned by backgrinding to separate the wafer 3900 to individual semiconductor dies 4400. A die attach material 4402 is also applied to the non-device sides of the semiconductor dies 4400. FIGS. 45A-C are cross-sectional, top-down, and perspective views of a die pad 4500 and conductive terminals 4502. FIGS. 46A-C are cross-sectional, top-down, and perspective views of one of the semiconductor dies 4400 of FIGS. 44A-C coupled to the die pad 4500, and FIGS. 47A-C are cross-sectional, top-down, and perspective views of bond wires 4700 coupling the semiconductor die 4400 to the conductive terminals 4502. FIGS. 48A-C are cross-sectional, top-down, and perspective views of the structure of FIGS. 47A-C, except that a mold compound 4800 is applied to cover the various structures of FIGS. 47A-C. The mold compound 4800 does not enter the cavity 4302, because the mold compound dam 4300 precludes entry of the mold compound 4800 into the cavity 4302 during the mold application process.

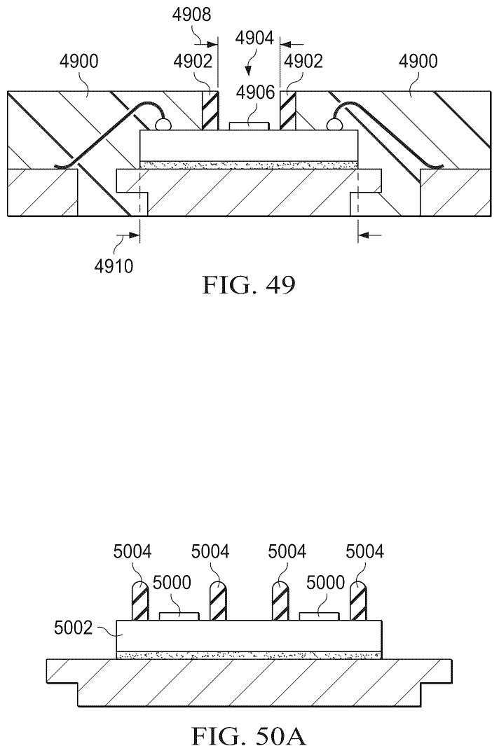

The mold compound dams described herein facilitate a decrease in the size of the semiconductor packages in which the mold compound dams are included. FIG. 49 is a cross-sectional view of a semiconductor package 4900 including a mold compound dam 4902 having features similar to those of the various mold compound dams described herein (e.g., mold compound dams 204). Inclusion of the mold compound dam 4902 enables the cavity 4904 above the sensor 4906 to be substantially smaller than would otherwise be the case, achieving at least an 83% reduction in maximal cavity diameter 4908. Furthermore, because the cavity size is reduced and no longer needs to be large, the size of the semiconductor die in the horizontal plane (numeral 4910) also may be reduced by at least 33.75%, thereby facilitating a smaller overall package size, or, alternatively or in addition, the inclusion of additional components within the semiconductor package 4900.

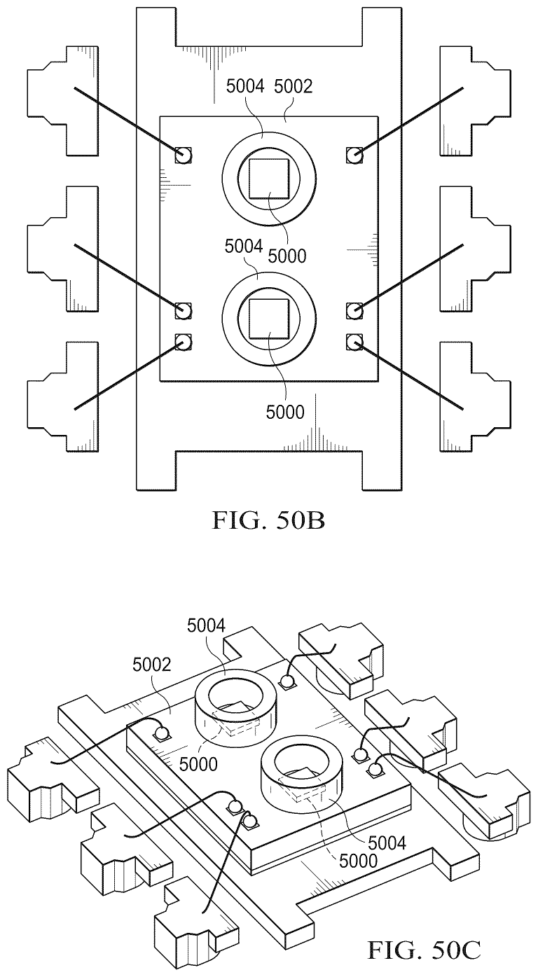

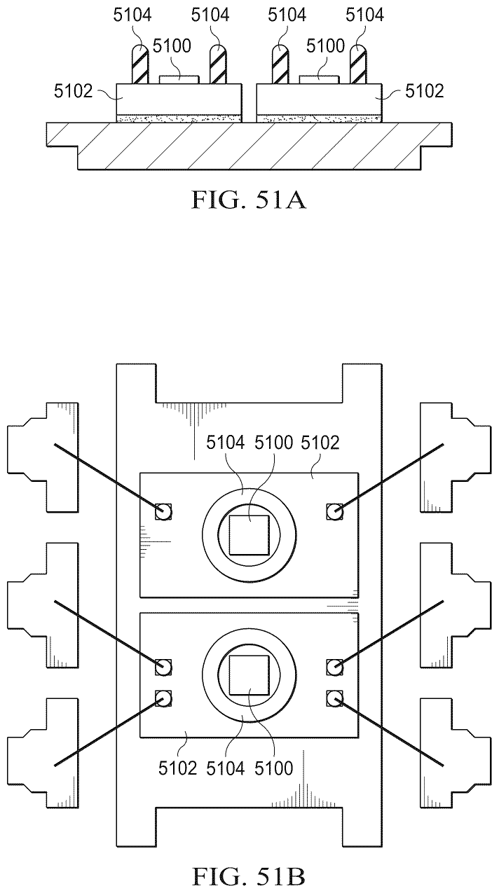

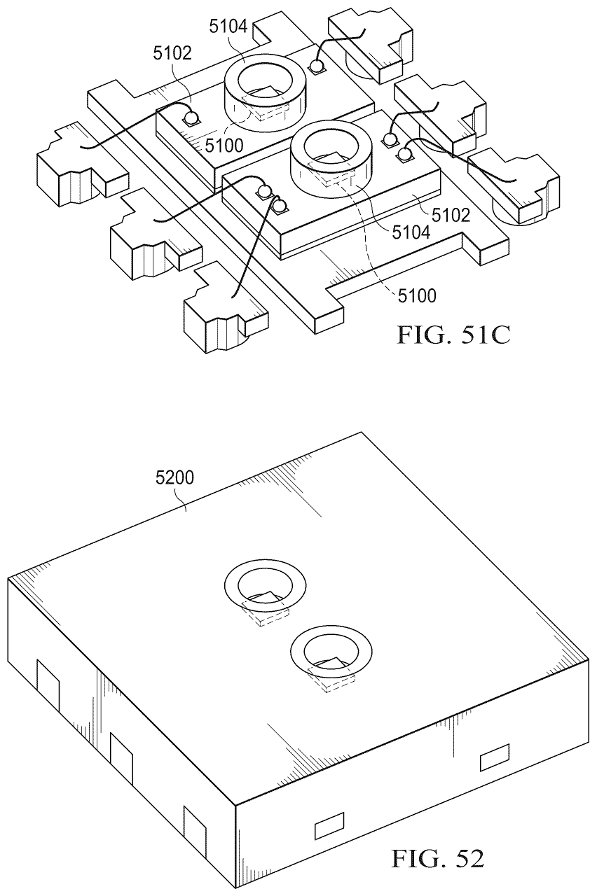

In some examples, a semiconductor package may include multiple sensors and multiple mold compound dams circumscribing those sensors. FIGS. 50A-C are cross-sectional, top-down, and perspective views of contents of a semiconductor package in which multiple sensors 5000 are included on a semiconductor die 5002, and a different mold compound dam 5004 circumscribes each of the sensors 5000. FIGS. 51A-C are cross-sectional, top-down, and perspective views of contents of a semiconductor package in which multiple sensors 5100 are distributed across multiple semiconductor dies 5102, with a different mold compound dam 5104 on each of the dies 5102, circumscribing a respective sensor 5100, as shown. FIG. 52 is a perspective view representative of both examples shown in FIGS. 50A-C and 51A-C, with a mold compound 5200 applied to cover the various structures shown in FIGS. 50A-C and 51A-C.

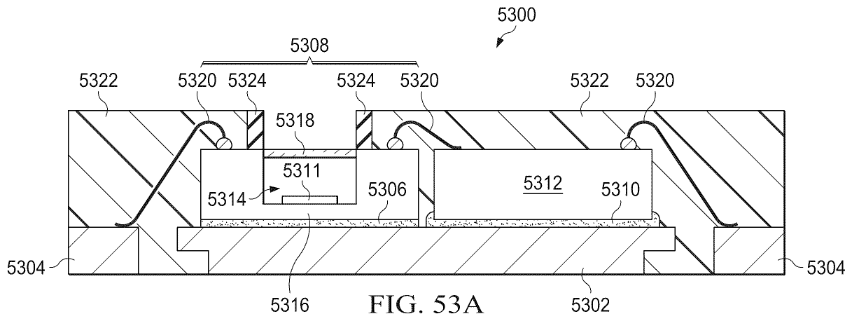

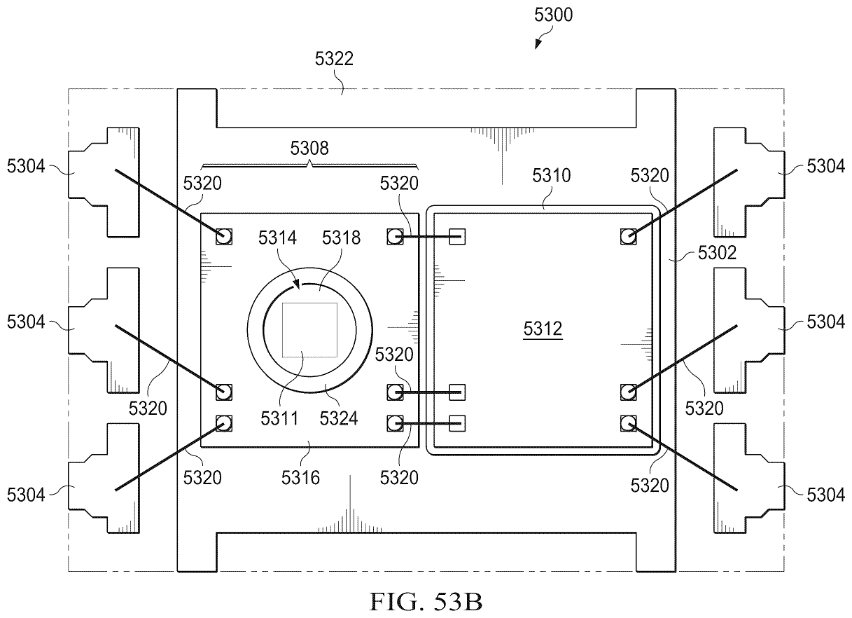

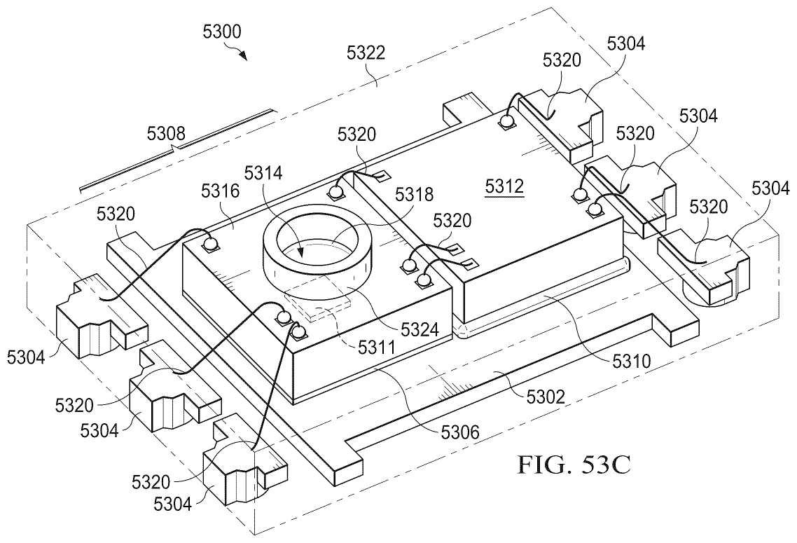

FIGS. 53A-C depict a semiconductor package manufactured according to the techniques described herein, in accordance with various examples. Specifically, FIGS. 53A-C show a semiconductor package 5300 including a die pad 5302, conductive terminals 5304, die attach film 5306 coupling a microelectromechanical systems (MEMS) device 5308 to the die pad 5302, and die attach film 5310 coupling a semiconductor die 5312 to the die pad 5302. The MEMS device 5308 may include a MEMS element 5311 (e.g., a micromirror array) in a cavity 5314 defined by a substrate 5316. The MEMS device 5308 may include additional components, such as circuitry, metal traces, etc., that are included in the semiconductor package 5300 but that are not expressly shown. In some examples, a lid 5318 (e.g., in optical applications, the lid 5318 is glass or another transparent material) covers the cavity 5314. Bond wires 5320 couple the MEMS device 5308 to the semiconductor die 5312, and couple the MEMS device 5308 and the semiconductor die 5312 to the conductive terminals 5304. The semiconductor package 5300 includes a mold compound 5322 covering the various structures depicted, and a mold compound dam 5324 precludes the mold compound 5322 from contacting or covering the MEMS device 5308, such as the lid 5318, and in examples lacking the lid 5318, from contacting or covering the MEMS element 5311. The description provided herein for the various other mold compound dams may apply in whole or in part to the mold compound dam 5324. The MEMS device 5308 may perform a specific function(s) and may provide and receive signals associated with those functions to and from the semiconductor die 5312. The semiconductor die 5312 may control aspects of the MEMS device 5308. The MEMS device 5308 and the semiconductor die 5312 may communicate with components outside of the semiconductor package 5300 through the conductive terminals 5304. The benefits provided by the mold compound dam 5324 are similar to those attributed herein to the various mold compound dams disclosed.

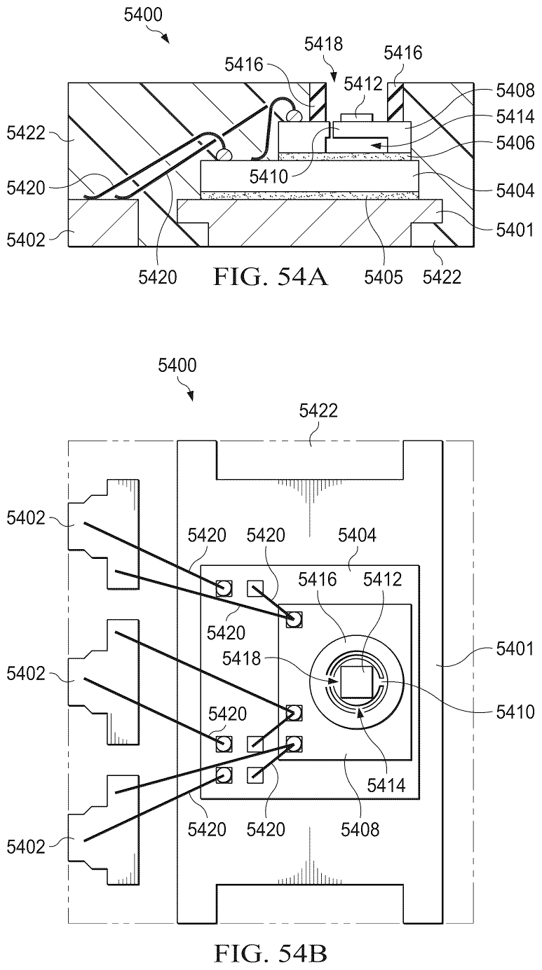

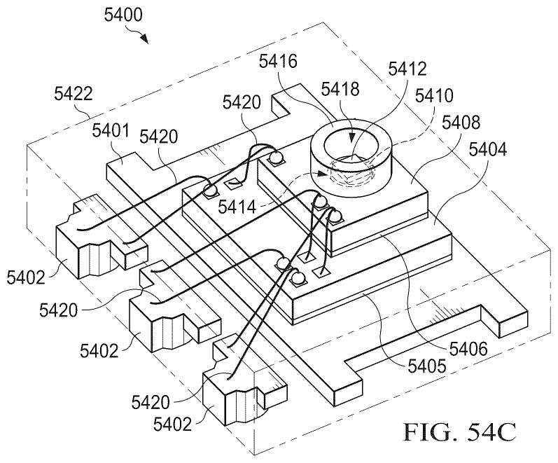

FIGS. 54A-C depict a semiconductor package 5400 manufactured according to the techniques described herein, in accordance with various examples. The package 5400 may include a die pad 5401, one or more conductive terminals 5402, and a semiconductor die 5404 coupled to the die pad 5401 (e.g., by a die attach material 5405). A die attach material 5406 couples a substrate 5408 (e.g., a ceramic substrate) to the semiconductor die 5404. A cantilevered portion 5410 extends from the substrate 5408 and is suspended above a cavity 5414 containing, e.g., air. A mold compound dam 5416 is positioned on the substrate 5408 as shown. The descriptions provided herein of the various mold compound dams may apply in whole or in part to the mold compound dam 5416. The mold compound dam 5416 circumscribes a cavity 5418 that is directly above the cantilevered portion 5410. The cantilevered portion 5410 includes a sensor 5412, which may be any suitable type of sensor, such as one that is sensitive to vibrations, heat, and/or other disturbances that may influence the accuracy of measurements taken by the sensor 5412. Bond wires 5420 couple the substrate 5408 (e.g., bond pads on the substrate 5408) to the semiconductor die 5404 (e.g., bond pads on the semiconductor die 5404). Similarly, bond wires 5420 couple the substrate 5408 and the semiconductor die 5404 to the conductive terminals 5402. A mold compound 5422 covers the various components of the semiconductor package 5400. The mold compound dam 5416 precludes flow of the mold compound 5422 into the cavity 5418 and onto the cantilevered portion 5410 and/or the sensor 5412 during application of the mold compound 5422.

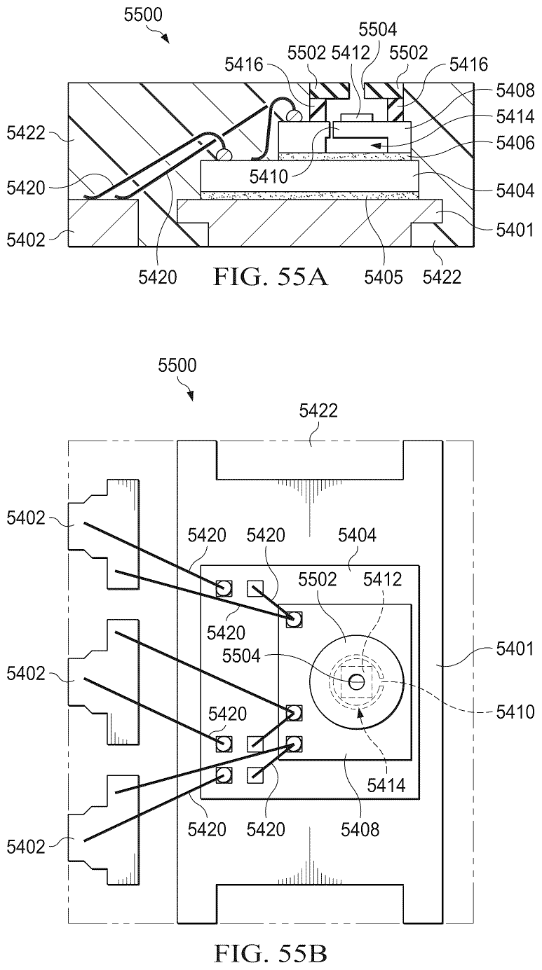

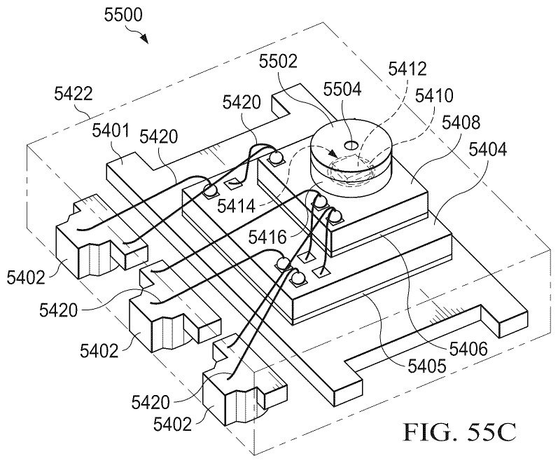

FIGS. 55A-C depict a semiconductor package 5500 manufactured according to the techniques described herein, in accordance with various examples. The semiconductor package 5500 is virtually identical to the semiconductor package 5400 (FIGS. 54A-C), except that a cantilevered portion 5502 having an orifice 5504 is included as part of the mold compound dam 5416 and is suspended over the sensor 5412, as shown. The descriptions provided herein of other cantilevered portions, such as the cantilevered portion 1006 and cantilevered portion 2006, may apply in whole or in part to the cantilevered portion 5502.

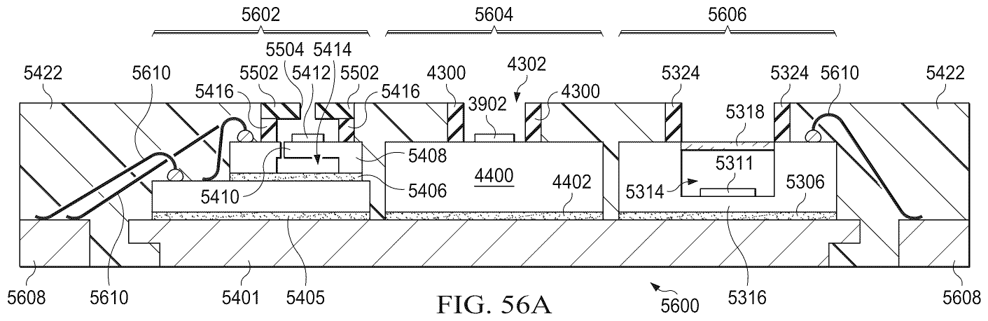

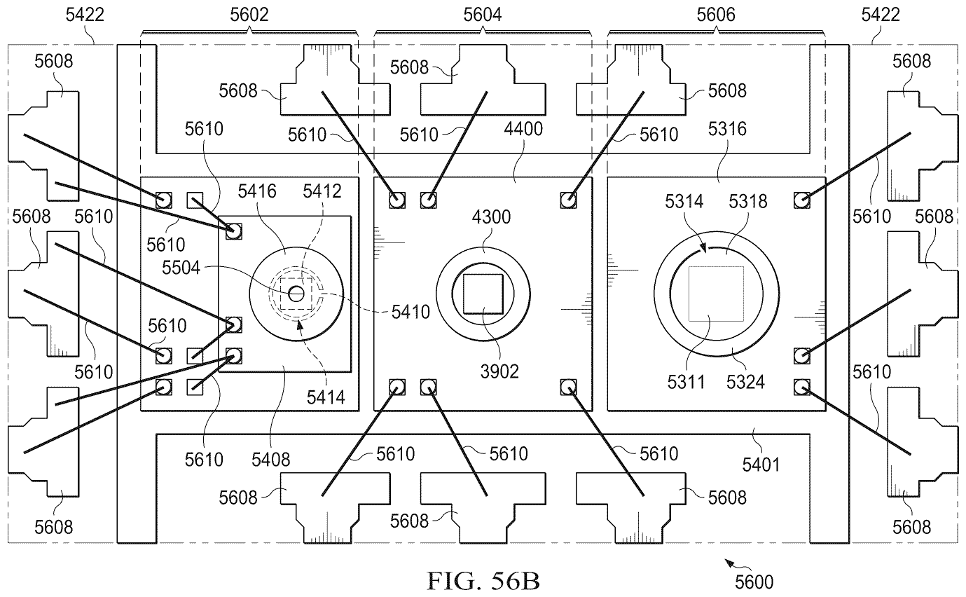

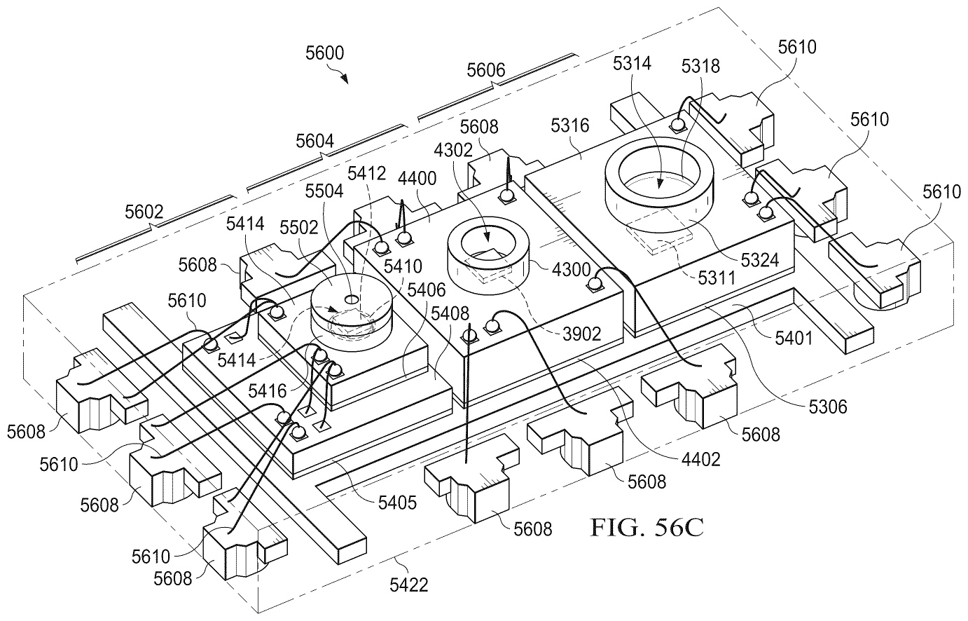

FIGS. 56A-C depict a semiconductor package 5600 manufactured according to the techniques described herein, in accordance with various examples. The semiconductor package 5600 includes multiple different types of sensor assemblies. For example, the package 5600 may include a sensor assembly 5602, which is similar to and is described herein with reference to FIGS. 54A-C and FIGS. 55A-C. Similarly, the package 5600 may include a sensor assembly 5604, which is similar to and is described herein with reference to FIGS. 2A-8C, FIGS. 30A-37C., and FIGS. 39A-48C. The package 5600 also may include a sensor assembly 5606, which is similar to and is described herein with reference to FIGS. 53A-C (e.g., a MEMS assembly). The various sensor assemblies 5602, 5604, and 5606 may be coupled to conductive terminals 5608 by bond wires 5610, as shown.

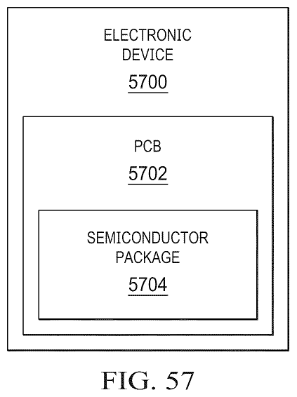

FIG. 57 is a block diagram of an electronic device 5700, in accordance with various examples. The electronic device 5700 may include a printed circuit board (PCB) 5702, to which a semiconductor package 5704 may be coupled. The semiconductor package 5704 may be any of the various semiconductor packages described herein. The electronic device 5700 may be any suitable type of system or device, such as an automobile, an aircraft, a watercraft, a spacecraft, a video game console, an arcade video game unit, a smartphone, an entertainment device, an appliance, a laptop computer, a desktop computer, a tablet, a notebook, or any other suitable type of system or device.

Any element or aspect of any example described herein may be combined with any other element(s) or aspect(s) of one or more other examples described herein, as appropriate. All such combinations and permutations are included within the scope of this disclosure. Similarly, descriptions of components provided herein may be applied in whole or in part to other, similar components described herein. All such descriptions are contemplated and included in the scope of this disclosure.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

In this description, unless otherwise stated, “about,” “approximately” or “substantially” preceding a parameter means being within +/−10 percent of that parameter. Modifications are possible in the described examples, and other examples are possible within the scope of the claims.

As used herein, terms such as “terminal,” “node,” “interconnection,” “pin,” and “lead” are used interchangeably. Unless specifically stated to the contrary, these terms are generally used to mean an interconnection between or a terminus of a device element, a circuit element, an integrated circuit, a device, or a semiconductor component.

What is claimed is:

1. A semiconductor package, comprising:
a semiconductor die including a device side having circuitry formed therein and a non-device side opposite the device side;
a mold compound dam on the device side, the mold compound dam comprising a non-metallic material; and
a mold compound on the device side of the semiconductor die and contacting an outer wall of the mold compound dam, the mold compound absent from a cavity defined by the mold compound dam.

2. The semiconductor package of claim 1, further comprising a sensor in the cavity, the sensor is cantilevered over a second cavity.

3. The semiconductor package of claim 1, wherein the non-metallic material is selected from the group consisting of polyimide and polybenzoxazole.

4. The semiconductor package of claim 1, further comprising a sensor in the cavity, wherein the sensor is a microelectromechanical systems (MEMS) device.

5. The semiconductor package of claim 1, further comprising a sensor in the cavity, wherein the mold compound dam comprises a cantilevered portion suspended above the sensor, the cantilevered portion having an orifice in axial alignment with the sensor.

6. The semiconductor package of claim 5, wherein the cantilevered portion has a uniform horizontal thickness from a top surface of the cantilevered portion to a bottom surface of the cantilevered portion.

7. The semiconductor package of claim 5, wherein the cantilevered portion comprises a film.

8. The semiconductor package of claim 5, wherein a vertical thickness of the cantilevered portion decreases from an outer surface of the cantilevered portion to an inner surface of the cantilevered portion.

9. The semiconductor package of claim 8, wherein the vertical thickness is measured from a top surface of the cantilevered portion to a bottom surface of the cantilevered portion.

10. A semiconductor package, comprising:
a semiconductor die including a device side having circuitry formed therein and a non-device side opposite the device side;
a sensor on the device side of the semiconductor die;
a mold compound dam on the device side and encircling the sensor, the mold compound dam comprising a non-metallic material and comprising a cantilevered portion distal to the sensor relative to the device side, the cantilevered portion suspended over the sensor and defining an orifice axially aligned with the sensor, the cantilevered portion having a decreasing thickness measured from a top surface of the cantilevered portion to a bottom surface of the cantilevered portion; and
a mold compound on the device side of the semiconductor die and contacting an outer wall of the mold compound dam facing away from the sensor, the mold compound absent from a cavity defined by the mold compound dam.

11. The semiconductor package of claim 10, wherein the orifice has a diameter ranging from 30 microns to 1000 microns.

12. The semiconductor package of claim 10, wherein the thickness decreases from an outer surface of the cantilevered portion to an inner surface of the cantilevered portion.

13. A semiconductor package, comprising:
a semiconductor die including a device side having circuitry formed therein and a non-device side opposite the device side;
a sensor on the device side of the semiconductor die;
a mold compound dam on the device side and encircling the sensor, the mold compound dam comprising a cantilevered portion distal to the sensor relative to the device side, the cantilevered portion suspended over the sensor and defining an orifice axially aligned with the sensor, the orifice having a diameter between 30 microns and 1000 microns, the cantilevered portion having an approximately uniform thickness from a top surface of the cantilevered portion to a bottom surface of the cantilevered portion; and
a mold compound on the device side of the semiconductor die and contacting an outer wall of the mold compound dam facing away from the sensor, the mold compound absent from a cavity defined by the mold compound dam.

14. The semiconductor package of claim 13, wherein the mold compound dam comprises an epoxy material.

15. The semiconductor package of claim 13, wherein the mold compound comprises polyimide or polybenzoxazole.

16. The semiconductor package of claim 13, wherein the cantilevered portion comprises a film.

17. The semiconductor package of claim 13, wherein the sensor is a microelectromechanical systems (MEMS) device.

18. A method for manufacturing a semiconductor package, comprising:
forming a mold compound dam circumscribing a sensor on a semiconductor wafer, the mold compound dam comprising a non-metallic material and comprising a cantilevered portion distal to the sensor relative to the semiconductor wafer, the cantilevered portion suspended over the sensor and defining an orifice axially aligned with the sensor, the orifice having a diameter between 30 microns and 1000 microns, the cantilevered portion having a decreasing thickness measured from a top surface of the cantilevered portion to a bottom surface of the cantilevered portion; and
back grinding and singulating the semiconductor wafer to produce a semiconductor die;
coupling the semiconductor die to a die pad;
wire bonding the semiconductor die to a conductive terminal; and
covering the semiconductor die, the die pad, and the conductive terminal with a mold compound, the mold compound dam precluding the mold compound from flowing into a cavity defined by the mold compound dam and precluding the mold compound from contacting the sensor.

19. The method of claim 18, wherein forming the mold compound dam comprises using a printing technique selected from the group consisting of: inkjet printing, nano imprinting, and stencil printing.

20. The method of claim 18, wherein the sensor is cantilevered over a second cavity.

21. The method of claim 18, wherein the non-metallic material is selected from the group consisting of polyimide and polybenzoxazole.

22. The method of claim 18, wherein the sensor is a microelectromechanical systems (MEMS) device.

23. The method of claim 18, wherein the thickness decreases from an outer surface of the cantilevered portion to an inner surface of the cantilevered portion.

24. A method for manufacturing a semiconductor package, comprising:
forming a mold compound dam circumscribing a sensor on a semiconductor wafer, the mold compound dam comprising a non-metallic material;
film-laminating a cantilevered portion on the mold compound dam, the cantilevered portion distal to the sensor relative to the semiconductor wafer, the cantilevered portion suspended over the sensor and defining an orifice axially aligned with the sensor, the cantilevered portion having a uniform thickness from an outer surface of the cantilevered portion to an inner surface of the cantilevered portion; and
backgrinding and singulating the semiconductor wafer to produce a semiconductor die;
coupling the semiconductor die to a die pad;
wire bonding the semiconductor die to a conductive terminal; and
covering the semiconductor die, the die pad, and the conductive terminal with a mold compound, the mold compound dam precluding the mold compound from flowing into a cavity defined by the mold compound dam and precluding the mold compound from contacting the sensor.

25. The method of claim 24, wherein the orifice has a diameter ranging from 30 microns to 1000 microns.

26. The method of claim 24, wherein the thickness is measured from a top surface of the cantilevered portion to a bottom surface of the cantilevered portion.
